(19) United States
(12) Patent Application Publication
(10) Pub. No.: US 2025/0056961 A1
(43) Pub. Date: Feb. 13, 2025

(54) DISPLAY PANELS

(71) Applicant: Wuhan China Star Optoelectronics Semiconductor Display Technology Co., Ltd., Wuhan (CN)

(72) Inventors: Kailong WU, Wuhan (CN); Yu GU, Wuhan (CN); Munjae LEE, Wuhan (CN); Xianjie LI, Wuhan (CN)

(21) Appl. No.: 18/520,828

(22) Filed: Nov. 28, 2023

Related U.S. Application Data
(63) Continuation of application No. PCT/CN2023/120926, filed on Sep. 25, 2023.

(30) Foreign Application Priority Data
Jul. 31, 2023 (CN) 202310956467.2

(51) Int. Cl. H10K 50/13; H10K 50/155; H10K 50/165; H10K 59/35

(52) U.S. Cl. CPC H10K 50/131; H10K 50/155; H10K 50/165; H10K 59/35; H10K 2101/30; H10K 2101/40; H10K 2102/351

(57) ABSTRACT

Embodiments of the present disclosure provide a display panel comprising a light-emitting element, in which the light-emitting element includes a first electrode layer, a first light-emitting layer, a first buffer layer, a first charge-generating layer, a second buffer layer, a second light-emitting layer, and a second electrode layer; in which the first charge-generating layer includes a first n-type charge-generating layer and a first p-type charge-generating layer, and both of the electron mobility of the first buffer layer and the electron mobility of the second buffer layer are less than the electron mobility of the first n-type charge-generating layer.

### CROSS REFERENCE TO RELATED APPLICATIONS

This application is a national Stage of International Application No. PCT/CN2023/120926, filed on Sep. 25, 2023, which claims priority to and the benefit of Chinese Patent Application No. 202310956467.2, filed on Jul. 31, 2023. The disclosures of the aforementioned applications are incorporated herein by reference in their entireties.

### TECHNICAL FIELD

The present disclosure relates to the field of display, and in particular, to display panels.

### BACKGROUND

At present, organic light-emitting devices have attracted widespread attention in the field of display due to their excellent properties such as thin profile, light weight, high-speed response to input signals, and capable of achieving driving of DC low voltages. In an organic light-emitting device having multiple first light-emitting units, it is necessary to set an n-type charge-generating layer and a p-type charge-generating layer between the multiple light-emitting units to provide electrons and holes for the light-emitting units, respectively. As shown in FIG. 1, the direct contact between the p-type and n-type charge-generating layers leads to a technical problem of unstable operation of the device caused by sensitivity of reverse charges when the operation temperature is high.

Therefore, there is an urgent need for a display panel to solve the above-mentioned technical problem.

### SUMMARY

Embodiments of the present disclosure provides a display panel, including:
a substrate;
a first electrode layer disposed on a side of the substrate;
a first light-emitting layer disposed on a side of the first electrode layer away from the substrate;
a first buffer layer disposed on a side of the first light-emitting layer away from the substrate;
a first charge-generating layer disposed on a side of the first buffer layer away from the substrate, in which the first charge-generating layer includes a first n-type charge-generating layer disposed on a side of the first buffer layer away from the substrate and a first p-type charge-generating layer disposed on a side of the first n-type charge-generating layer away from the substrate;
a second buffer layer disposed between the first n-type charge-generating layer and the first p-type charge-generating layer;
a second light-emitting layer disposed on a side of the first charge-generating layer away from the substrate; and
a second electrode layer disposed on a side of the second light-emitting layer away from the substrate;
in which the electron mobility of the first buffer layer is less than the electron mobility of the first n-type charge-generating layer, and the electron mobility of the second buffer layer is less than the electron mobility of the first n-type charge-generating layer;
a difference between the highest occupied molecular orbital energy level of the first buffer layer and the lowest unoccupied molecular orbital energy level of the first n-type charge-generating layer is greater than 2 eV and less than 4 eV; and
a difference between the highest occupied molecular orbital energy level of the second buffer layer and the lowest unoccupied molecular orbital energy level of the first n-type charge-generating layer is greater than 2 eV and less than 4 eV.

### BRIEF DESCRIPTION OF THE DRAWINGS

FIG. 1 is a schematic structural diagram of a charge-generating layer of a light-emitting element in the prior art.

FIG. 2 is a schematic structural diagram of a first structure of a light-emitting element in a display panel provided by some embodiments of the present disclosure.

FIG. 3 is a schematic structural diagram of a structure of a charge-generating layer, a first buffer layer, and a second buffer layer of a light-emitting element in a display panel provided by some embodiments of the present disclosure.

FIG. 4 is a schematic structural diagram of a second structure of a light-emitting element in a display panel provided by some embodiments of the present disclosure.

FIG. 5 is a schematic structural diagram of a structure of a charge-generating layer, a first buffer layer, a second buffer layer, a third buffer layer, and a fourth buffer layer of a light-emitting element in a display panel provided by some embodiments of the present disclosure.

FIG. 6 is a schematic structural diagram of a display panel provided by some embodiments of the present disclosure.

### DETAILED DESCRIPTION

The present disclosure provides a display panel. In order to make the purpose, technical solutions, and effects of the present disclosure clearer and more definite, the following will provide further detailed explanations of the present disclosure with embodiments with reference to the attached drawings. It should be understood that, the specific embodiments described here are only used to explain the present disclosure and are not intended to limit it.

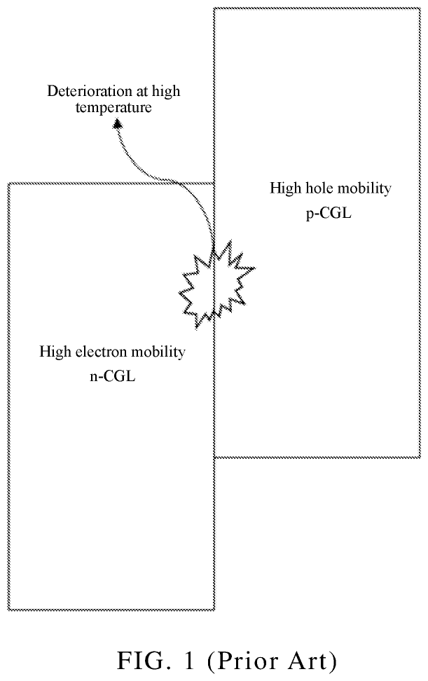

Referring to FIG. 1, at present, in organic light-emitting devices having multiple light-emitting layers, a n-type charge generation sub-layer (n-CGL) and a p-type charge generation sub-layer (p-CGL) are in direct contact, resulting in the technical problems of unstable operation and deterioration at high temperature of the light-emitting devices caused by sensitivity of reverse charges of the light-emitting devices at high operation temperature.

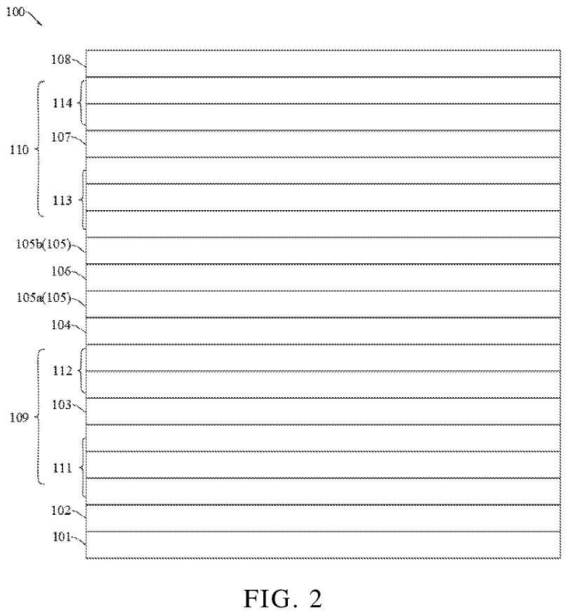

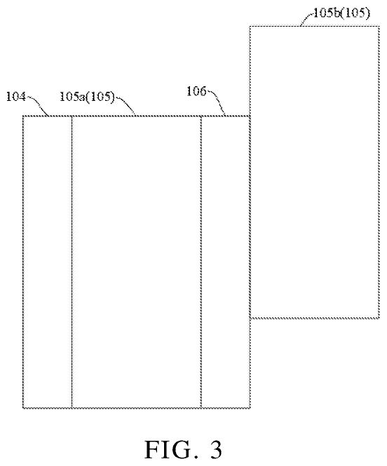

Referring to FIGS. 2 to 6, embodiments of the present disclosure provide a display panel 10, which includes:
a substrate 101;
a first electrode layer 102 disposed on a side of the substrate 101;
a first light-emitting layer 103 disposed on a side of the first electrode layer 102 away from the substrate 101;
a first buffer layer 104 disposed on a side of the first light-emitting layer 103 away from the substrate 101;
a first charge-generating layer 105 disposed on a side of the first buffer layer 104 away from the substrate 101, the first charge-generating layer 105 includes a first n-type charge-generating layer 105a disposed on a side of the first buffer layer 104 away from the substrate 101 and a first p-type charge-generating layer 105b disposed on a side of the first n-type charge-generating layer 105a away from the substrate 101;
a second buffer layer 106 disposed between the first n-type charge-generating layer 105a and the first p-type charge-generating layer 105b;
a second light-emitting layer 107 disposed on a side of the first charge-generating layer 105 away from the substrate 101; and
a second electrode layer 108 disposed on a side of the second light-emitting layer 107 away from the substrate 101;
in which the electron mobility of the first buffer layer 104 is less than the electron mobility of the first n-type charge-generating layer 105a, and the electron mobility of the second buffer layer 106 is less than the electron mobility of the first n-type charge-generating layer 105a;
a difference between the highest occupied molecular orbital energy level of the first buffer layer 104 and the lowest unoccupied molecular orbital energy level of the first n-type charge-generating layer 105a is greater than 2 eV and less than 4 eV; and
a difference between the highest occupied molecular orbital energy level of the second buffer layer 106 and the lowest unoccupied molecular orbital energy level of the first n-type charge-generating layer 105a is greater than 2 eV and less than 4 eV.

Embodiments of the present disclosure, by setting the first buffer layer 104 and the second buffer layer 106 on opposite two sides of the first n-type charge-generating layer 105a, and both of the electron mobility of the first buffer layer 104 and the electron mobility of the second buffer layer 106 being less than the electron mobility of the first n-type charge-generating layer 105a, improve sensitivity of reverse charges generated by the direct contact between the first n-type charge-generating layer 105a and the first p-type charge-generating layer 105b. Moreover, the first buffer layer 104 and the second buffer layer 106 play a role in blocking holes between the first n-type charge-generating layer 105a and the first light-emitting layer 103, which improves the operation stability of a display panel 10 at high temperature.

Technical solutions of the present disclosure are described in conjunction with specific embodiments below.

Referring to FIGS. 2 to 6, in some embodiments, a light-emitting element 100 in the display panel 10 may be composed of a cathode, an anode, at least two adjacent light-emitting units, a charge-generating layer, and a buffer layer. The two adjacent light-emitting units are a first light-emitting unit 109 and a second light-emitting unit 110, respectively. The first light-emitting unit 109 includes the first light-emitting layer 103. The second light-emitting unit 110 includes the second light-emitting layer 107. The charge-generating layer is disposed between adjacent light-emitting units and includes the first charge-generating layer 105. The buffer layer is disposed between adjacent light-emitting units and includes the first buffer layer 104 and the second buffer layer 106.

The first electrode layer 102 may be an anode, and the second electrode layer 108 may be a cathode.

A material of the anode is preferably selected from at least one of a metal, an alloy, and a conductive compound. Specifically, the material of the anode may be a metal oxide such as indium tin oxide, indium zinc oxide, indium zinc tungsten oxide, indium tin zinc oxide, zinc oxide, or graphene, gold, platinum, nickel, tungsten, chromium, molybdenum, or nitrides of metal materials.

A material of the cathode is preferably a material having a work function less than a work function of the anode, preferably selected from at least one of a metal, an alloy, and a conductive compound. Specifically, the material of the cathode may include an alkali metal, an alkali-earth metal, or a rare-earth metal, such as Ag, Mg, Cu, Al, Pt, Pd, Au, Ni, Nd, Ir, Cr, Li, Ca, LiF/Ca, LiF/Al, Mo, Ti, Yb, W, a Mg—Ag alloy, an Al—Li alloy, or the like. Alternatively, the material of the second electrode layer 108 may also be selected from indium tin oxide, indium zinc oxide, zinc oxide, indium tin zinc oxide, or a combination of optional materials for the cathode.

Referring to FIGS. 2 to 5, in some embodiments, the number of the light-emitting units disposed between the first electrode layer 102 and the second electrode layer 108 may be greater than or equal to two, that is, the light-emitting units may include the first light-emitting unit 109, the second light-emitting unit 110 . . . Nth light-emitting unit, in which N is an integer greater than or equal to 3. For example, the number of the light-emitting units may be two, three, or the like. The charge-generating layer is disposed at least between two adjacent light-emitting units. Preferably, when there are more than two light-emitting units disposed between the first electrode layer 102 and the second electrode layer 108, the charge-generating layer is disposed between each two adjacent light-emitting units, for example, the first charge-generating layer 105 disposed between the first light-emitting unit 109 and the second light-emitting unit 110. The buffer layer is disposed at least between two adjacent light-emitting units, for example, the first buffer layer 104 disposed between the first light-emitting unit 109 and the first n-type charge-generating layer 105a, and the second buffer layer 106 disposed between the first n-type charge-generating layer 105a and the first p-type charge-generating layer 105b.

Each light-emitting unit is composed of a hole transport layer, a light-emitting layer, and an electron transport layer stacked sequentially. When the first electrode layer 102 is an anode and the second electrode layer 108 is a cathode, each light-emitting unit is composed of a hole transport layer, a light-emitting layer, and an electron transport layer stacked sequentially in a direction from the first electrode layer 102 to the second electrode layer 10. For example, the first light-emitting unit 109 is composed of a first hole transport layer 111, the first light-emitting layer 103, and a first electron transport layer 112 stacked sequentially; and the second emitting unit 110 is composed of a second hole transport layer 113, the second light-emitting layer 107, and a second electron transport layer 114 stacked sequentially.

The hole transport layer may include a hole transport sub-layer. For example, the first hole transport layer 111 includes a first hole transport sub-layer, and the second hole transport layer 113 includes a second hole transport sub-layer. Alternatively, the hole transport layer may also include a hole injection sub-layer, for example, the first hole transport layer 111 includes a first hole injection sub-layer, and the second hole transport layer 113 includes a second hole injection sub-layer. Alternatively, the hole transport layer may also include an electron blocking sub-layer. For example, the first hole transport layer 111 includes a first hole electron blocking sub-layer, and the second hole transport layer 113 includes a second electron blocking sub-layer. The hole injection sub-layer may include a hole injection material, which may be selected from a metal oxide such as molybdenum oxide, titanium oxide, tungsten oxide, silver oxide, or the like; a phthalocyanine compound such as copper phthalocyanine; a carbazole-based derivative such as N-phenyl carbazole or polyvinyl carbazole; a fluorene-based derivative; a triphenylamine-based derivative such as N,N′-bis(3-methylphenyl)-N,N′-diphenyl-[1,1-biphenyl]-4,4′-diamine (TPD), 4,4′,4″-tris(N-carbazolyl) triphenylamine (TCTA), N,N′-bis(naphthalene 1-yl)-N,N′-diphenylbenzidine (NPB), 4,4′-cyclohexylidene-bis[N, N-bis(4-methylphenyl) aniline](TAPC), 4,4′-bis[N,N′-(3-tolyl)amino]-3,3′-dimethylbiphenyl (HMTPD), 9-(4-tert-butylphenyl)-3,6-bis(triphenylsilyl)-9H-carbazole (CzSi), 9-phenyl-9H-3,9′-bicarbazole (CCP), 1,3-bis(N-carbazolyl) benzene (mCP), 1,3-bis (1,8-dimethyl-9H-carbazole-9-yl) benzene (mDCP), or combinations thereof. The electron blocking sub-layer includes an electron blocking material, which may be selected from an aromatic amine compound, such as a triarylamine-based compound.

The electron transport layer may include an electron transport sub-layer, for example, the first electron transport layer 112 includes a first electron transport sub-layer, and the second electron transport layer 114 includes a second electron transport sub-layer. Alternatively, the electron transport layer also includes an electron injection sub-layer, for example, the first electron transport layer 112 includes a first electron injection sub-layer, and the second electron transport layer 114 includes a second electron injection sub-layer. Alternatively, the electron transport layer also includes a hole blocking sub-layer, for example, the first electron transport layer 112 includes a first hole blocking sub-layer, and the second electron transport layer 114 includes a second hole blocking sub-layer. The electron injection sub-layer includes an electron injection material, which may be selected from an alkali metal, an alkali-earth metal, a rare-earth metal, an alkali metal compound, an alkali-earth metal compound, a rare-earth metal compound, or the like, such as lithium, lithium fluoride, lithium oxide, calcium fluoride, ytterbium, Liq, KI, NaCl, CsF, Li₂O, BaO, or the like. A work function of the electron injection sub-layer is less than a work function of the cathode, which is beneficial to inject electrons into the electron transport sub-layer. A material of the hole blocking sub-layer may include a heteroaromatic compound, such as a derivative of triazine pyrimidine, or the like.

Referring to FIGS. 2 to 5, in some embodiments, among all the light-emitting units disposed between the first electrode layer 102 and the second electrode layer 108, the hole transport layer of the light-emitting unit closest to the anode is composed of the hole injection sub-layer, the hole transport sub-layer, and the electron blocking sub-layer stacked sequentially, the hole injection sub-layer is disposed on a side of the hole transport sub-layer close to the anode, and the electron blocking sub-layer is disposed between the hole transport sub-layer and the light-emitting layer. Among all the light-emitting units disposed between the first electrode layer 102 and the second electrode layer 108, the hole transport layer of each of light-emitting units, except for the light-emitting unit closest to the anode, is composed of the hole transport sub-layer and the electron blocking sub-layer stacked sequentially, and the electron blocking sub-layer is disposed between the hole transport sub-layer and the light-emitting layer.

In some embodiments, among all the light-emitting units disposed between the first electrode layer 102 and the second electrode layer 108, the electron transport layer of the light-emitting unit closest to the cathode is composed of the electron injection sub-layer, the electron transport sub-layer, and the hole blocking sub-layer stacked sequentially, the electron injection sub-layer is disposed on a side of the electron transport sub-layer 1 close to the cathode, and the hole blocking sub-layer is disposed between the electron transport sub-layer and the light-emitting layer. Among all the light-emitting units disposed between the first electrode layer 102 and the second electrode layer 108, the electron transport layer of each of light-emitting units, except for the light-emitting unit closest to the cathode, is composed of the electron transport sub-layer and the hole blocking sub-layer stacked sequentially, and the hole blocking sub-layer is disposed between the electron transport sub-layer and the light-emitting layer.

Emission colors of light-emitting layers in at least two adjacent light-emitting units may be the same or different.

The light-emitting layer includes a host material. In some embodiments, the host material may be selected from a compound represented by the following formula (1):

[Ar₁₀₁]ₘ₃[(L₁₀₁)ₓ₃-R₁₁x₁₁][(L₁₀₂)_{y3}-R₁₂y₁₁][(L₁₀₃)_{z3}-R₁₃z₁₁] (1);

Ar₁₀₁ may be a substituted or unsubstituted carbon ring group having 5 to 60 carbon atoms, or a substituted or unsubstituted heterocyclic group having 1 to 60 carbon atoms,

M3 may be selected from 1, 2, or 3,

L₁₀₁, L₁₀₂, and L₁₀₃ may be independently selected from a substituted or unsubstituted cycloalkylene group having 3 to 10 carbon atoms, a substituted or unsubstituted heterocyclic alkylene group having 1 to 10 carbon atoms, a substituted or unsubstituted cycloalkenyl group having 3 to 10 carbon atoms, a substituted or unsubstituted heterocyclic alkenyl group having 1 to 10 carbon atoms, a substituted or unsubstituted arylene group having 6 to 60 carbon atoms, a substituted or unsubstituted hetero-arylene group having 1 to 60 carbon atoms, a substituted or unsubstituted divalent non-aromatic fused polycyclic group or divalent non-aromatic fused heteropolycyclic group,

x3, y3, and z3 may be independently selected from any one of integers from 0 to 5,

R₁₁, R₁₂, and R₁₃ are independently selected from deuterium, —H, —F, —Cl, —Br, —I, a hydroxyl group, a cyano group, a nitro group, an amidine group, a hydrazine group, a hydrazone group, a substituted or unsubstituted alkyl group having 1 to 60 carbon atoms, a substituted or unsubstituted alkenyl group having 2 to 60 carbon atoms, a substituted or unsubstituted alkynyl group having 2 to 60 carbon atoms, a substituted or unsubstituted alkoxyl group having 1 to 60 carbon atoms, a substituted or unsubstituted cycloalkyl group having 3 to 10 carbon atoms, a substituted or unsubstituted heterocyclic alkyl group having 1 to 10 carbon atoms, a substituted or unsubstituted cycloalkenyl group having 3 to 10 carbon atoms, a substituted or unsubstituted heterocyclic alkenyl group having 1 to 10 carbon atoms, a substituted or unsubstituted aryl group having 6 to 60 carbon atoms, a substituted or unsubstituted aryloxy group having 6 to 60 carbon atoms, a substituted or unsubstituted aryl thiol group having 6 to 60 carbon atoms, a substituted or unsubstituted heteroaryl group having 1 to 60 carbon atoms, a substituted or unsubstituted monovalent non-aromatic fused polycyclic group, a substituted or unsubstituted monovalent non-aromatic fused heteropolycyclic group, —Si(Q₁₀₁)(Q₁₀₂)(Q₁₀₃), —N(Q₁₀₁)(Q₁₀₂), —B(Q₁₀₁)(Q₁₀₂), —C(═O)(Q₁₀₁), —S(═O)₂(Q₁₀₁), or —P(═O)(Q₁₀₁)(Q₁₀₂),

x11, y11, and z11 may be independently selected from any one of integers from 0 to 5, and

Q₁₀₁, Q₁₀₂, and Q₁₀₃ may be independently selected from an alkyl group having 1 to 10 carbon atoms, an alkoxyl group having 1 to 10 carbon atoms, a phenyl group, a biphenyl group, a triphenyl group, a naphthyl group, or the like.

In some embodiments, L₁₀₁, L₁₀₂, and L₁₀₃ may be independently selected from one of the following formula (1-1), formula (1-1), and formula (1-3):

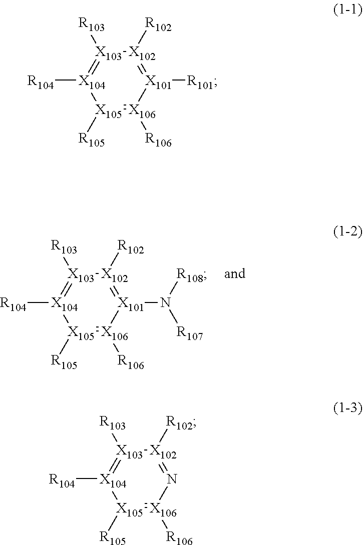

X₁₀₁ to X₁₀₆ are independently selected from C, O, S, or N-[(L₁₀₄)_{xb1}-R₁₀₇],

R₁₀₁ to R₁₀₆ may be independently selected from hydrogen, deuterium, —F, —Cl, —Br, —I, a hydroxyl group, a cyano group, a nitro group, an amidine group, a hydrazine group, a hydrazone group, an alkyl group having 1 to 20 carbon atoms, an alkoxyl group having 1 to 20 carbon atoms, a phenyl group, a biphenyl group, a triphenyl group, a naphthyl group, —Si(Q₁₀₁)(Q₁₀₂)(Q₁₀₃), —N(Q₁₀₁)(Q₁₀₂), —B(Q₁₀₁)(Q₁₀₂), —C(═0)(Q₁₀₁), —S(═O)₂(Q₁₀₁), or —P(=0)(Q₁₀₁)(Q₁₀₂),

L₁₀₄ is defined in the same way as L₁₀₁, L₁₀₂, and L₁₀₃, and R₁₀₇ is defined in the same way as R₁₀₁, R₁₀₂, and R₁₀₃, and

xb1 is an integer selected from 0 to 2.

In some embodiments, the host material is selected from one or more of the following compounds:

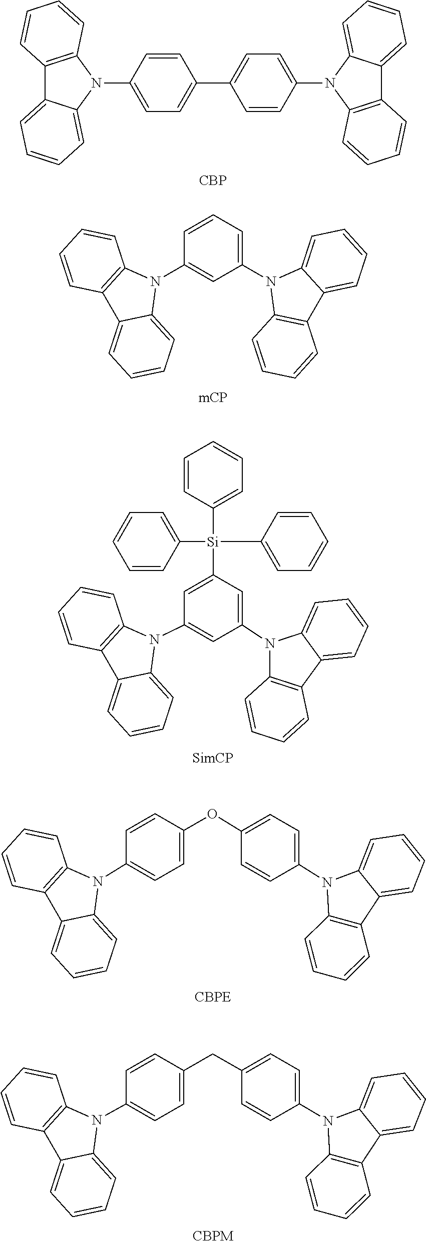

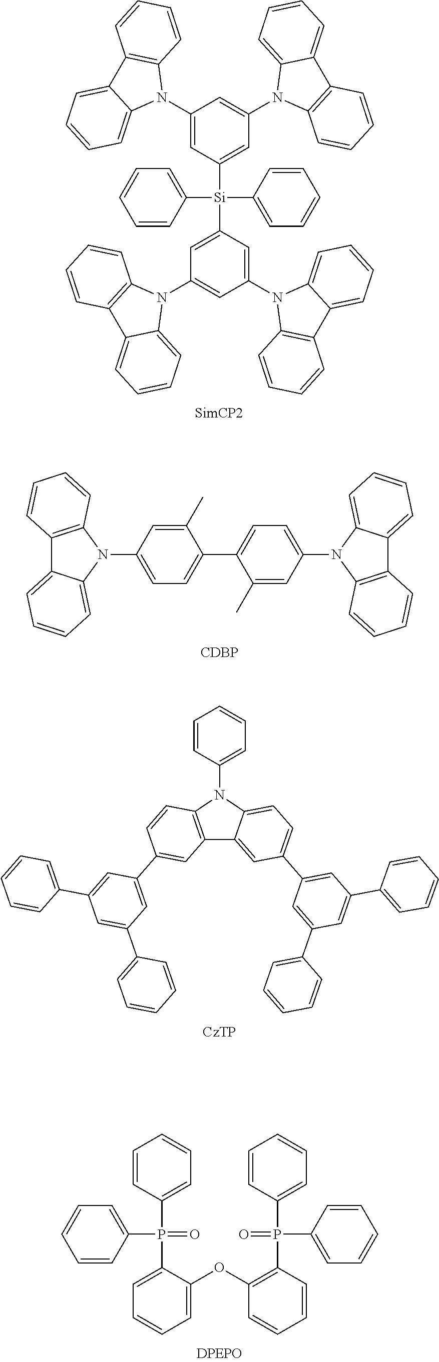

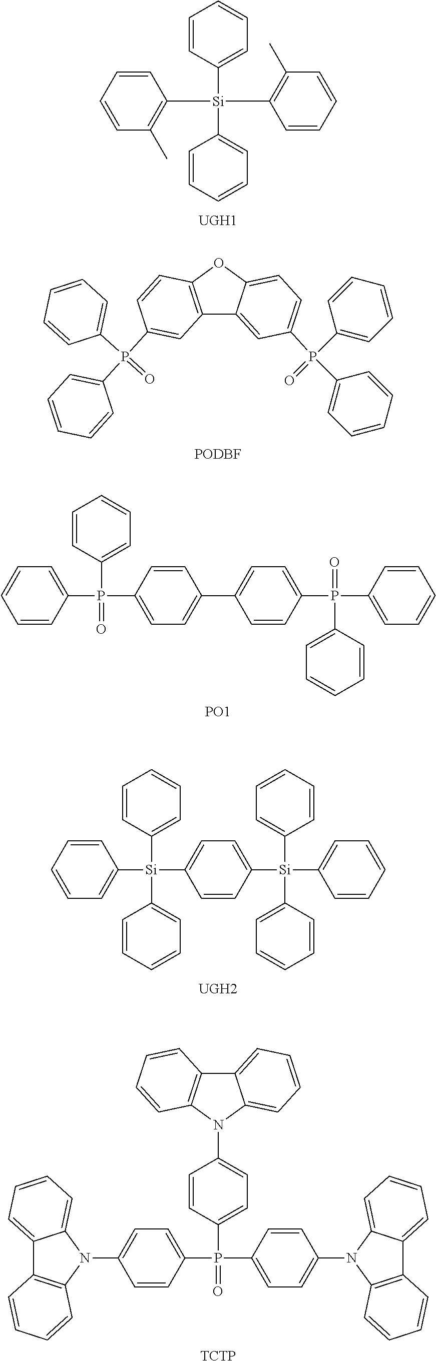

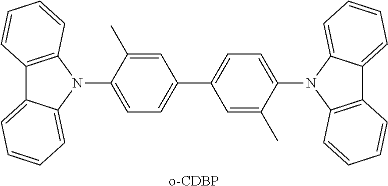 [SMILES: Cc1cc(-c2ccc(-n3c4ccccc4c4ccccc43)c(C)c2)ccc1-n1c2ccccc2c2ccccc21 ; "o-CDBP"]

In some embodiments, the host material may be selected from one or more of the following compounds:

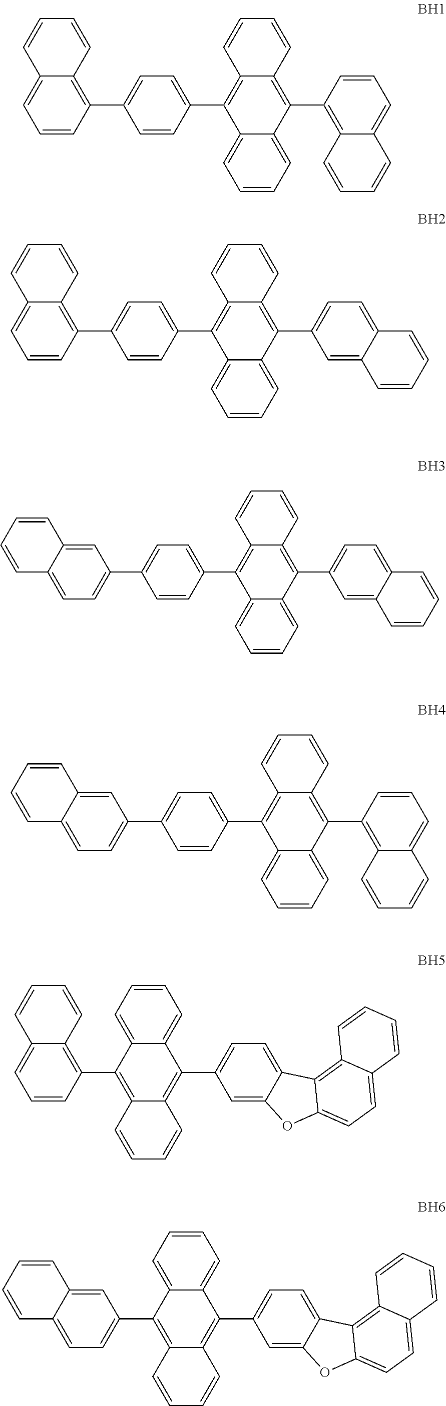

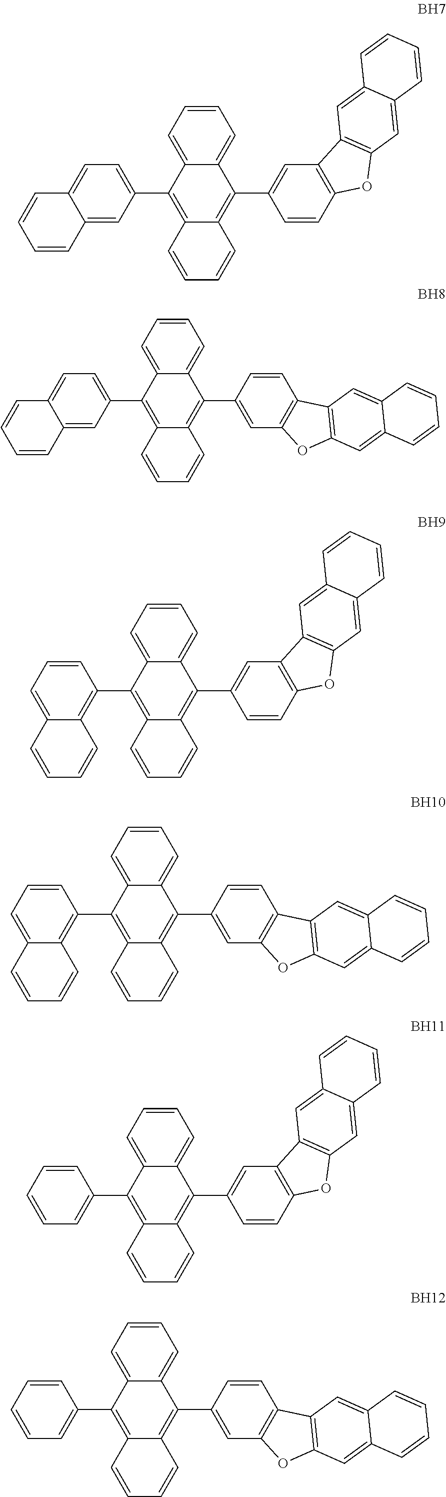

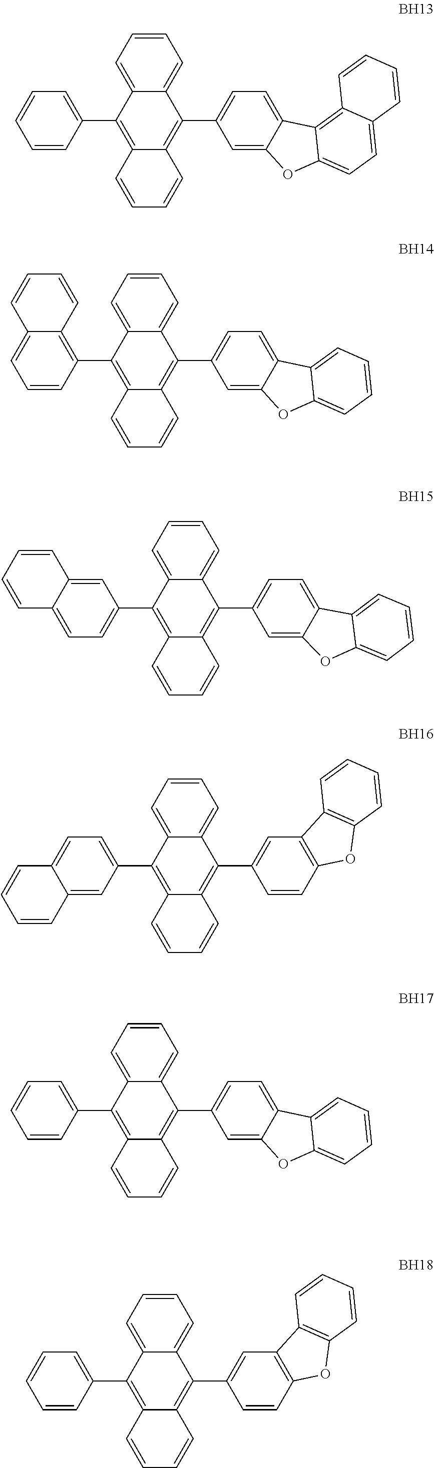 [SMILES: c1ccc(-c2c3ccccc3c(-c3ccc4c(c3)oc3ccc5ccccc5c34)c3ccccc23)cc1 ; c1ccc2c(-c3c4ccccc4c(-c4ccc5c(c4)oc4ccccc45)c4ccccc34)cccc2c1 ; c1ccc2cc(-c3c4ccccc4c(-c4ccc5c(c4)oc4ccccc45)c4ccccc34)ccc2c1 ; c1ccc2cc(-c3c4ccccc4c(-c4ccc5oc6ccccc6c5c4)c4ccccc34)ccc2c1 ; c1ccc(-c2c3ccccc3c(-c3ccc4c(c3)oc3ccccc34)c3ccccc23)cc1 ; c1ccc(-c2c3ccccc3c(-c3ccc4oc5ccccc5c4c3)c3ccccc23)cc1]

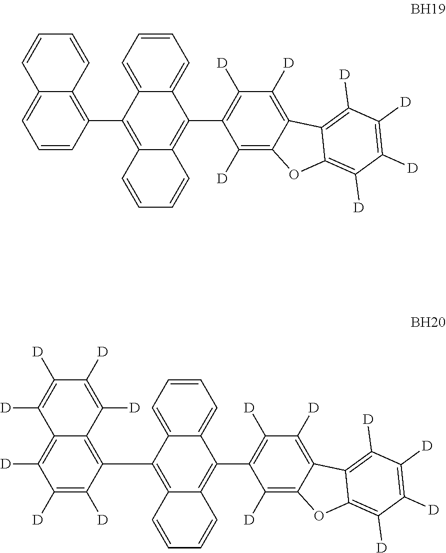 [SMILES: [2H]c1c([2H])c([2H])c2c(oc3c([2H])c(-c4c5ccccc5c(-c5cccc6ccccc56)c5ccccc45)c([2H])c([2H])c32)c1[2H] ; [2H]c1c([2H])c([2H])c2c(oc3c([2H])c(-c4c5ccccc5c(-c5c([2H])c([2H])c([2H])c6c([2H])c([2H])c([2H])c([2H])c56)c5ccccc45)c([2H])c([2H])c32)c1[2H]]

In some embodiments, the light-emitting layer also includes a doped material, which may be selected from an organic metal complex having a structure represented by the following formula (2-1):

Mₘ₂(L₂₀₁)ₓ₂(L₂₀₂)_{y2}(L₂₀₃)_{z2} (2-1);

in which M may be selected from iridium (Ir), platinum (Pt), palladium (Pd), osmium (Os), titanium (Ti), zirconium (Zr), hafnium (Hf), europium (Eu), terbium (Tb), rhodium (Rh), or thulium (Tm),

L₂₀₁, L₂₀₂, and L₂₀₃ may be independently selected from any one of ligands represented by the following formula (201) to formula (206):

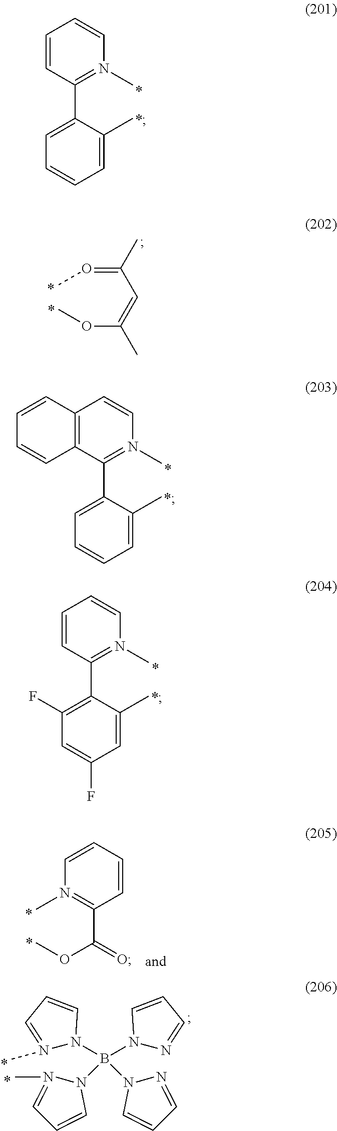

in which “*” indicates a coordination site, and

x2, y2, and z2 are independently selected from any one of integers from 0 to 3.

In some embodiments, the doped material is selected from one or more of the following compounds:

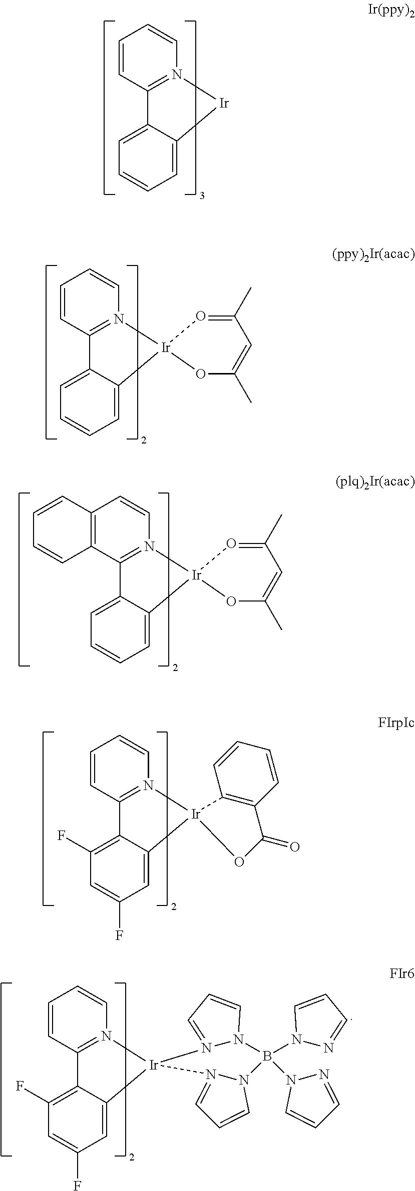

In some embodiments, the doped material is selected from a compound represented by the following formula (2-2):

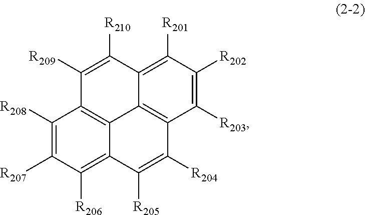

in which R₂₀₁ to R₂₁₀ are independently selected from hydrogen, deuterium, —F, —Cl, —Br, —I, a hydroxyl group, a cyano group, a nitro group, an amidine group, a hydrazine group, a hydrazone group, an alkyl group having 1 to 20 carbon atoms, an alkoxyl group having 1 to 20 carbon atoms, a substituted or unsubstituted aromatic amino group having 6 to 60 carbon atoms, or a substituted or unsubstituted heteroaromatic amino group having 5 to 60 carbon atoms.

In some embodiments, the doped material is selected from one or more of the following compounds:

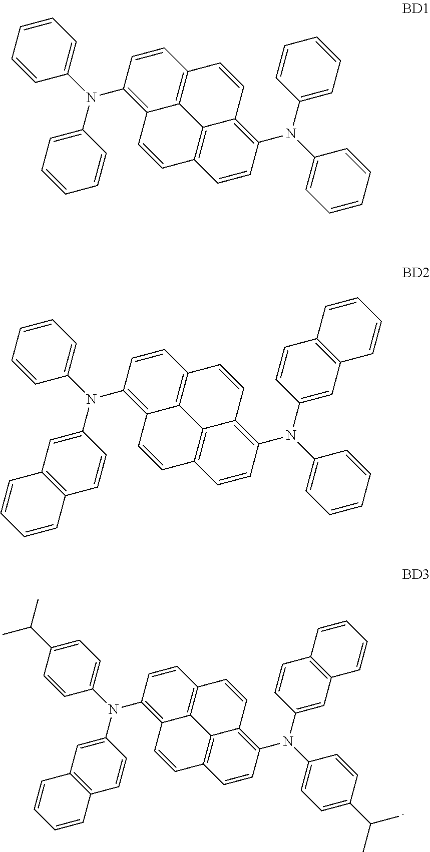 [SMILES: c1ccc(N(c2ccccc2)c2ccc3ccc4c(N(c5ccccc5)c5ccccc5)ccc5ccc2c3c54)cc1 ; c1ccc(N(c2ccc3ccccc3c2)c2ccc3ccc4c(N(c5ccccc5)c5ccc6ccccc6c5)ccc5ccc2c3c54)cc1 ; CC(C)c1ccc(N(c2ccc3ccccc3c2)c2ccc3ccc4c(N(c5ccc(C(C)C)cc5)c5ccc6ccccc6c5)ccc5ccc2c3c54)cc1]

In some embodiments, the doped material is selected from a compound having a structure represented by the following formula (2-3):

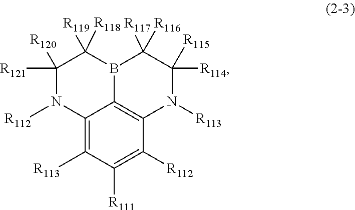

in which R₁₁₁ to R₁₂₁ are independently selected from hydrogen, deuterium, —F, —Cl, —Br, —I, a hydroxyl group, a cyano group, a nitro group, an amidine group, a hydrazine group, a hydrazone group, an alkyl group having 1 to 20 carbon atoms, an alkoxyl group having 1 to 20 carbon atoms, a substituted or unsubstituted cycloalkyl group having 3 to 10 carbon atoms, a substituted or unsubstituted heterocyclic alkyl group having 1 to 10 carbon atoms, a substituted or unsubstituted cycloalkenyl group having 3 to 10 carbon atoms, a substituted or unsubstituted heterocyclic alkenyl group having 1 to 10 carbon atoms, a substituted or unsubstituted aryl group having 6 to 60 carbon atoms, a substituted or unsubstituted heteroaryl group having 5 to 60 carbon atoms, a substituted or unsubstituted divalent non-aromatic fused polycyclic group, or a substituted or unsubstituted divalent non-aromatic fused heteropolycyclic group.

In some embodiments, the doped material is selected from one or more of DABNA-1, DABNA-2 or PtON-TBBI:

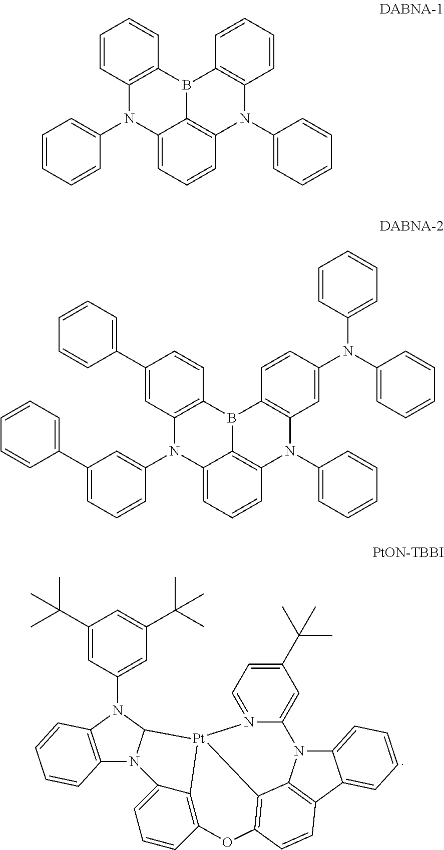

In some embodiments, the doped material may also be selected from one or more of the following compounds:

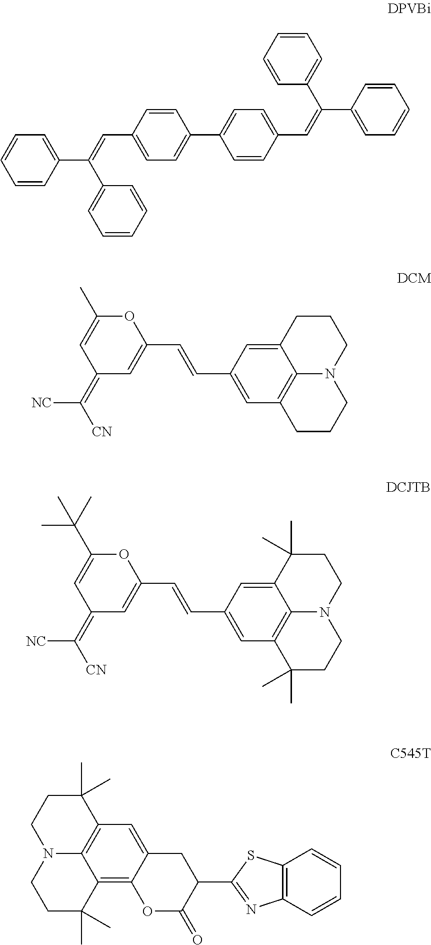

Referring to FIGS. 2 to 5, in some embodiments, a side of the first buffer layer 104 close to the first n-type charge-generating layer 105a is in direct contact with the first n-type charge-generating layer 105a, and a side of the first buffer layer 104 away from the first n-type charge-generating layer 105a is in direct contact with the first electron transport layer 112.

A side of the second buffer layer 106 close to the first n-type charge-generating layer 105a is in direct contact with the first n-type charge-generating layer 105a, and a side of the second buffer layer 106 away from the first n-type charge-generating layer 105a is in direct contact with the first p-type charge-generating layer 105b.

The first buffer layer 104 has one first buffer sub-layer, or, the first buffer layer 104 has multiple first buffer sub-layers. When the first buffer layer 104 has one first buffer sub-layer, a side of the first buffer layer 104 close to the first n-type charge-generating layer 105a is in direct contact with the first n-type charge-generating layer 105a, and a side of the first buffer sub-layer away from the first n-type charge-generating layer 105a is in direct contact with the first electron transport layer 112.

In some embodiments, the second buffer layer 106 has one second buffer sub-layer, or the second buffer layer 106 has multiple second buffer sub-layers. When the second buffer layer 106 has one second buffer sub-layer, a side of the second buffer sub-layer close to the first n-type charge-generating layer 105a is in direct contact with the first n-type charge-generating layer 105a. When the second buffer layer 106 has multiple second buffer sub-layers, a side of one of the multiple second buffer sub-layers closest to the first n-type charge-generating layer 105a is in direct contact with the first n-type charge-generating layer 105a.

In some embodiments, only the second buffer layer 106 is disposed between the first n-type charge-generating layer 105a and the first p-type charge-generating layer 105b, and a side of at least one second buffer layer 106 close to the first p-type charge-generating layer 105b is in direct contact with the first p-type charge-generating layer 105b. When the second buffer layer 106 is a single layer, two sides of the second buffer layer 106 are in direct contact with the first n-type charge-generating layer 105a and the first p-type charge-generating layer 105b, respectively, in a direction from the first electrode layer 102 to the second electrode layer 108. When the second buffer layer 106 is a multi-layer, a side of one of second buffer sub-layers in the second buffer layer 106 closest to the first n-type charge-generating layer 105a is in direct contact with the first n-type charge-generating layer 105a, and a side of one of the second buffer sub-layers closest to the first p-type charge-generating layer 105b is in direct contact with the first p-type charge-generating layer 105b, in the direction from the first electrode layer 102 to the second electrode layer 108.

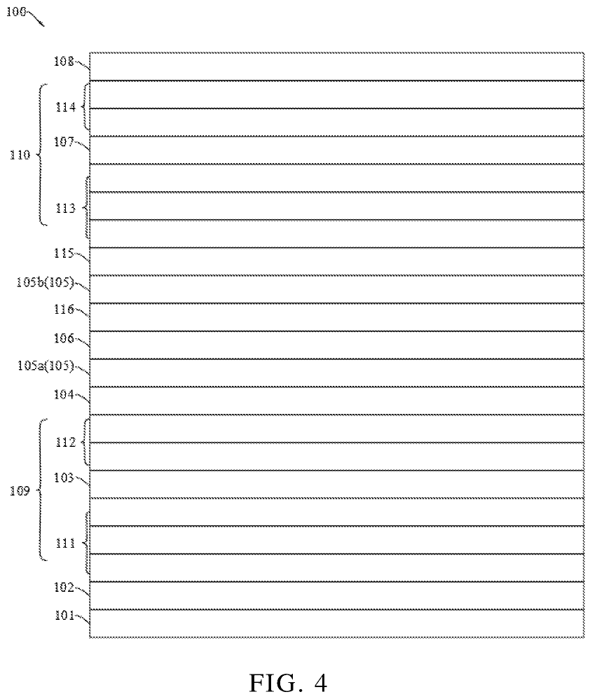

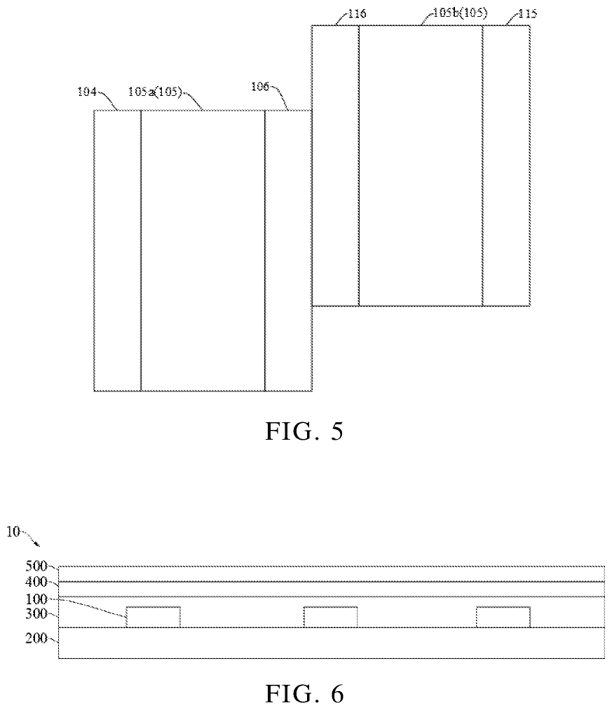

Referring to FIG. 4 and FIG. 5, in some embodiments, the display panel 10 further includes a third buffer layer 115 disposed between the first p-type charge-generating layer 105b and the second light-emitting layer 107.

The hole mobility of the third buffer layer 115 is less than the hole mobility of the first p-type charge-generating layer 105b.

A difference between the lowest unoccupied molecular orbital energy level of the third buffer layer 115 and the highest occupied molecular orbital energy level of the first p-type charge-generating layer 105b is greater than 2 eV and less than 4 eV.

In some embodiments, the display panel 10 further includes a fourth buffer layer 116 disposed between the first p-type charge-generating layer 105b and the second buffer layer 106.

The hole mobility of the fourth buffer layer 116 is less than the hole mobility of the first p-type charge-generating layer 105b.

A difference between the lowest unoccupied molecular orbital energy level of the fourth buffer layer 116 and the highest occupied molecular orbital energy level of the first p-type charge-generating layer 105b is greater than 2 eV and less than 4 eV.

In some embodiments, a side of the third buffer layer 115 close to the first p-type charge-generating layer 105b is in direct contact with the first p-type charge-generating layer 105b, and a side of the third buffer layer 115 away from the first p-type charge-generating layer 105b is in direct contact with the second hole transport layer 113.

In some embodiments, a side of the fourth buffer layer 116 close to the second buffer layer 106 is in direct contact with the second buffer layer 106, and a side of the fourth buffer layer 116 away from the second buffer layer 106 is in direct contact with the first p-type charge-generating layer 105b.

In some embodiments, the third buffer layer 115 may include one or more third buffer sub-layers. When the third buffer layer 115 has one third buffer sub-layer, a side of the one third buffer sub-layer close to the first p-type charge-generating layer 105b is in direct contact with the first p-type charge-generating layer 105b, and a side of the one third buffer sub-layer away from the first p-type charge-generating layer 105b is in direct contact with the second hole transport layer 113. When the third buffer layer 115 has multiple third buffer sub-layers stacked sequentially, one of the multiple third buffer sub-layers, which is closest to the first p-type charge-generating layer 105b, has a side being in direct contact with the first p-type charge-generating layer 105b, and one of the multiple third buffer sub-layers, which is closest to the second hole transport layer 113, has a side being in direct contact with the hole transport layer.

In some embodiments, the fourth buffer layer 116 may include one or more fourth buffer sub-layers. When the fourth buffer layer 116 has one fourth buffer sub-layer, a side of the one fourth buffer sub-layer close to the first n-type charge-generating layer 105a is in direct contact with the second buffer layer 106, and a side of the one fourth buffer sub-layer away from the second buffer layer 106 is in direct contact with the first p-type charge-generating layer 105b. When the fourth buffer layer 116 has multiple fourth buffer sub-layers stacked sequentially, one fourth buffer sub-layer among the multiple fourth buffer sub-layers, which is closest to the second buffer layer 106, has a side being in direct contact with the second buffer layer 106, and one fourth buffer sub-layer among the multiple fourth buffer sub-layers, which is closest to the first p-type charge-generating layer 105b, has a side being in direct contact with the first p-type charge-generating layer 105b.

In some embodiments, the first n-type charge-generating layer 105a includes a first electron transport material, and the first buffer layer 104 includes a second electron transport material.

The first electron transport material and the second electron transport material are selected from at least one of derivatives of pyridine, derivatives of pyrimidine, derivatives of triazine, derivatives of imidazole, derivatives of oxazole, and derivatives of phenanthroline.

In some embodiments, the first electron transport material and the second electron transport material are independently selected from a compound represented by the following formula (3):

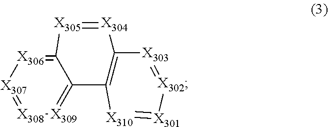

in which X₃₀₁ to X₃₀₉ are independently selected from C, N, a pyridinyl, a group having a derivative of pyridine, a pyridyl, a group having a derivative of pyrimidine, a triazinyl group, a group having a derivative of triazine, an imidazolyl, a group having a derivative of imidazole, an oxazolyl, a group having a derivative of oxazole, a phenanthroline group, or a group having a derivative of quinoline.

In some embodiments, the first electron transport material and the second electron transport material are independently selected from one or more of the following compounds:

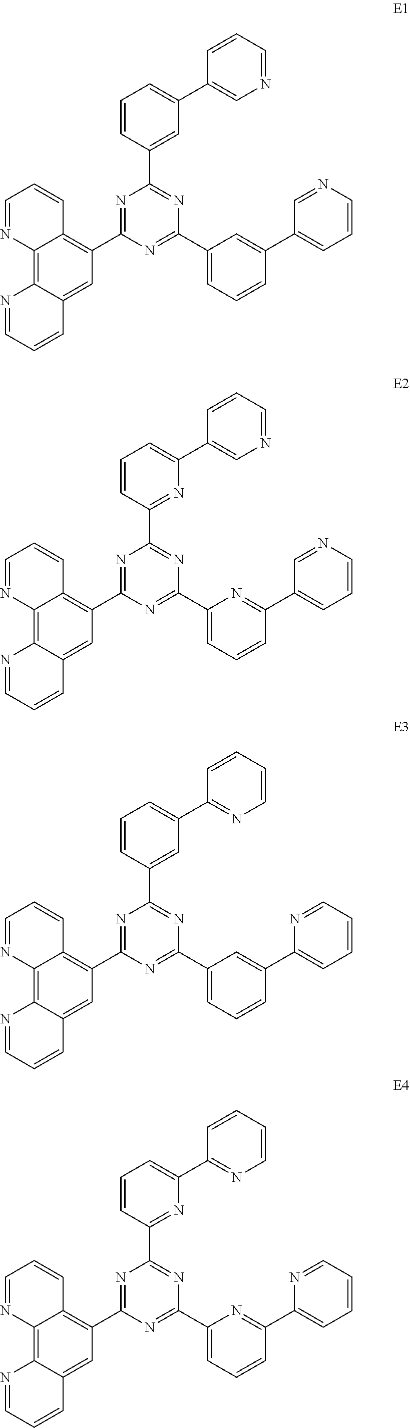 [SMILES: c1cncc(-c2cccc(-c3nc(-c4cccc(-c5cccnc5)c4)nc(-c4cc5cccnc5c5ncccc45)n3)c2)c1 ; c1cncc(-c2cccc(-c3nc(-c4cccc(-c5cccnc5)n4)nc(-c4cc5cccnc5c5ncccc45)n3)n2)c1 ; c1ccc(-c2cccc(-c3nc(-c4cccc(-c5ccccn5)c4)nc(-c4cc5cccnc5c5ncccc45)n3)c2)nc1 ; c1ccc(-c2cccc(-c3nc(-c4cccc(-c5ccccn5)n4)nc(-c4cc5cccnc5c5ncccc45)n3)n2)nc1]

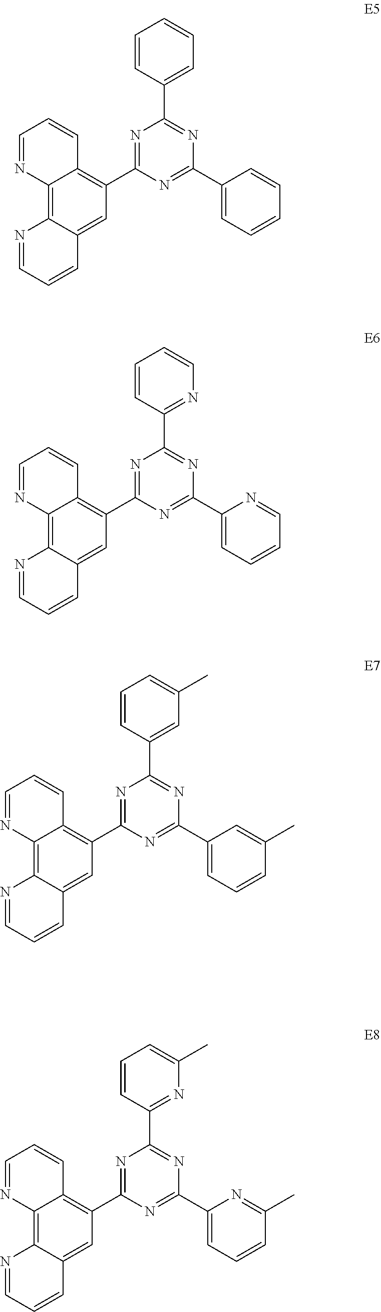 [SMILES: c1ccc(-c2nc(-c3ccccc3)nc(-c3cc4cccnc4c4ncccc34)n2)cc1 ; c1ccc(-c2nc(-c3ccccn3)nc(-c3cc4cccnc4c4ncccc34)n2)nc1 ; Cc1cccc(-c2nc(-c3cccc(C)c3)nc(-c3cc4cccnc4c4ncccc34)n2)c1 ; Cc1cccc(-c2nc(-c3cccc(C)n3)nc(-c3cc4cccnc4c4ncccc34)n2)n1]

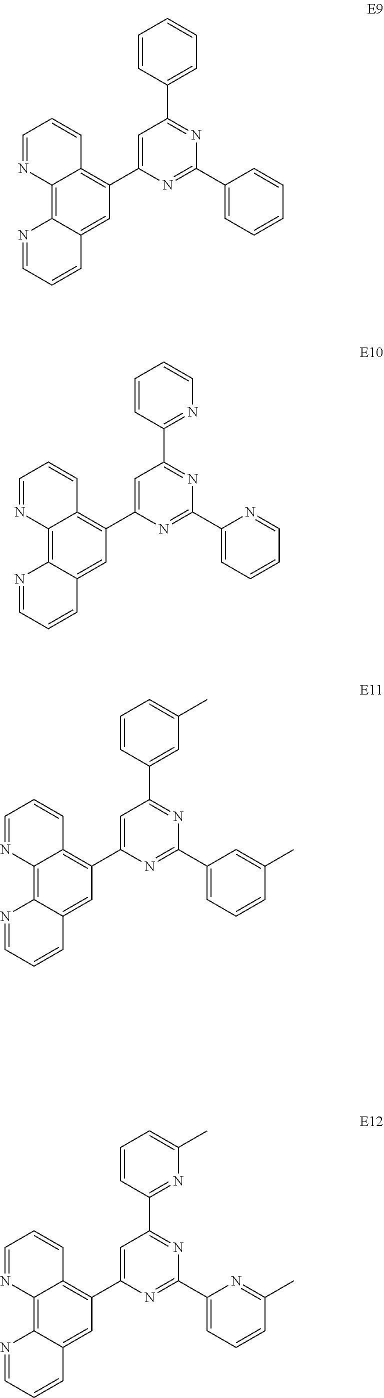 [SMILES: c1ccc(-c2cc(-c3cc4cccnc4c4ncccc34)nc(-c3ccccc3)n2)cc1 ; c1ccc(-c2cc(-c3cc4cccnc4c4ncccc34)nc(-c3ccccn3)n2)nc1 ; Cc1cccc(-c2cc(-c3cc4cccnc4c4ncccc34)nc(-c3cccc(C)c3)n2)c1 ; Cc1cccc(-c2cc(-c3cc4cccnc4c4ncccc34)nc(-c3cccc(C)n3)n2)n1]

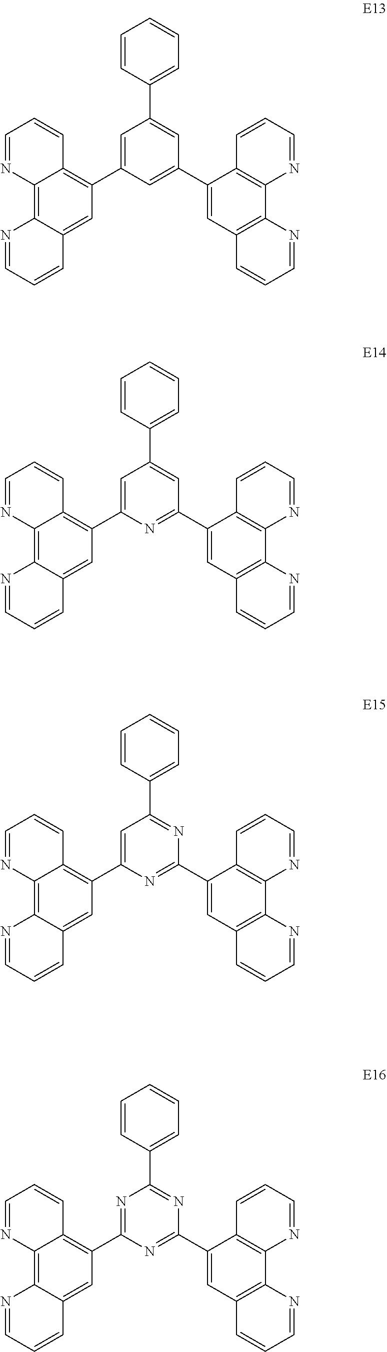 [SMILES: c1ccc(-c2cc(-c3cc4cccnc4c4ncccc34)cc(-c3cc4cccnc4c4ncccc34)c2)cc1 ; c1ccc(-c2cc(-c3cc4cccnc4c4ncccc34)nc(-c3cc4cccnc4c4ncccc34)c2)cc1 ; c1ccc(-c2cc(-c3cc4cccnc4c4ncccc34)nc(-c3cc4cccnc4c4ncccc34)n2)cc1 ; c1ccc(-c2nc(-c3cc4cccnc4c4ncccc34)nc(-c3cc4cccnc4c4ncccc34)n2)cc1]

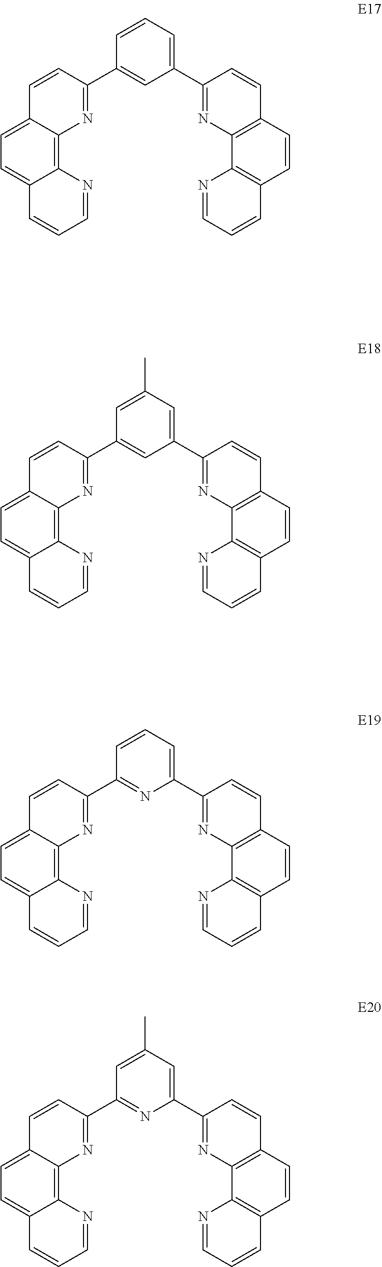 [SMILES: c1cc(-c2ccc3ccc4cccnc4c3n2)cc(-c2ccc3ccc4cccnc4c3n2)c1 ; Cc1cc(-c2ccc3ccc4cccnc4c3n2)cc(-c2ccc3ccc4cccnc4c3n2)c1 ; c1cc(-c2ccc3ccc4cccnc4c3n2)nc(-c2ccc3ccc4cccnc4c3n2)c1 ; Cc1cc(-c2ccc3ccc4cccnc4c3n2)nc(-c2ccc3ccc4cccnc4c3n2)c1]

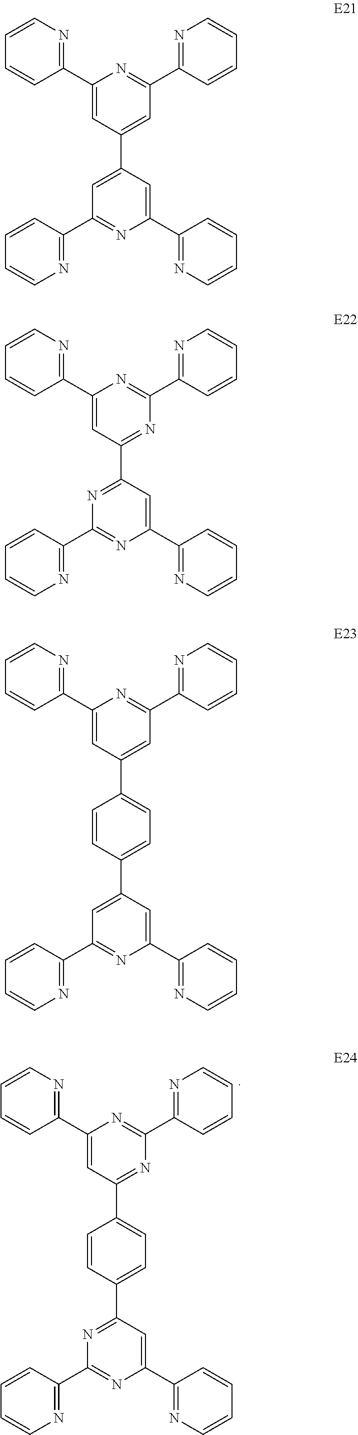

In some embodiments, the first buffer layer 104 is composed of the second electron transport material that is the same as the first electron transport material.

In some embodiments, the second buffer layer 106 is composed of the second electron transport material.

In some embodiments, a material of the first buffer layer 104 and a material of the second buffer layer 106 are the same, and both are the same as the first electron transport material.

In some embodiments, the first n-type charge-generating layer 105a also includes a first charge doped material. The first n-type charge-generating layer 105a may be composed of the first electron transport material and the first charge doped material.

The first charge doped material is selected from at least one of an alkali metal, an alloy of alkali metals, an alkali-earth metal, an alloy of alkali-earth metals, a lanthanide metal, and an alloy of lanthanide metals. The addition of the first charge doped material is beneficial to improve the electron mobility of the first n-type charge-generating layer 105a. Preferably, a mass ratio of the first electron transport material to the first charge doped material ranges from 99:1 to 80:20, for example, 98:2, 95:5, 92:8, 90:10, 88:12, 85:15, 82:18, or the like.

A selection range of a material of the electron transport sub-layer in the light-emitting unit may be the same as or different from the selection ranges of the first electron transport material and the second electron transport material.

In some embodiments, the material of the electron transport sub-layer may be selected from a compound represented by the following formula (4-1) or formula (4-2):

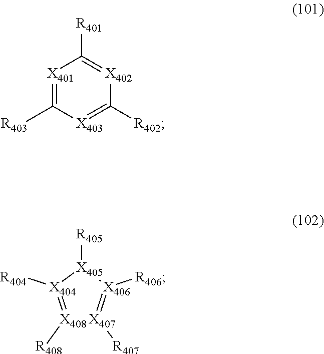

in which X₄₀₁ to X₄₀₈ are independently selected from C or N.

R₄₀₁ to R₄₀₈ are independently selected from hydrogen, deuterium, a substituted or unsubstituted cycloalkyl group having 3 to 10 carbon atoms, a substituted or unsubstituted heterocyclic alkyl group having 1 to 10 carbon atoms, a substituted or unsubstituted cycloalkenyl group having 3 to 10 carbon atoms, a substituted or unsubstituted heterocyclic alkenyl group having 1 to 10 carbon atoms, a substituted or unsubstituted aryl group having 6 to 60 carbon atoms, a substituted or unsubstituted heteroaryl group having 1 to 60 carbon atoms, a substituted or unsubstituted non-aromatic fused polycyclic group, or a substituted or unsubstituted non-aromatic fused heteropolycyclic group.

In some embodiments, the material of the electron transport sub-layer is selected from one or more of the following compounds:

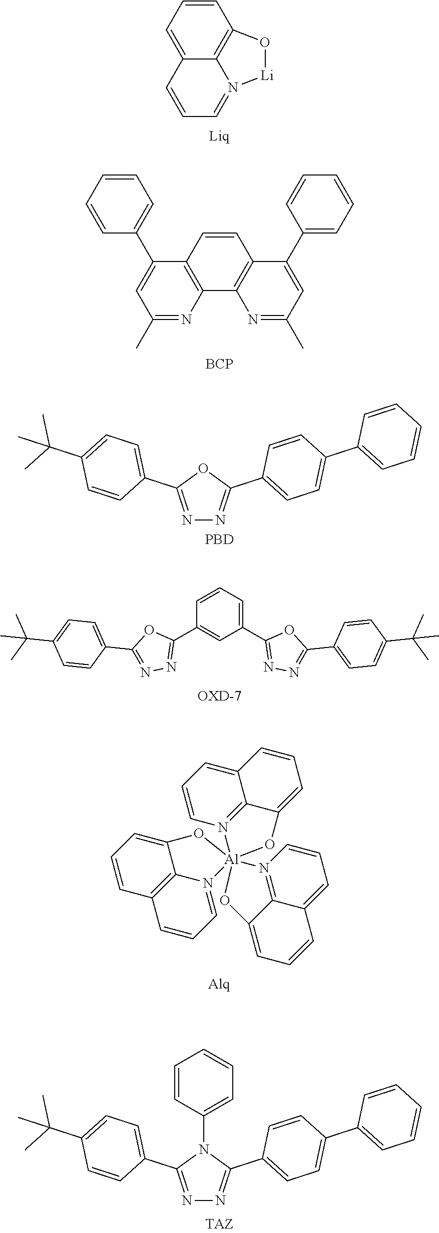

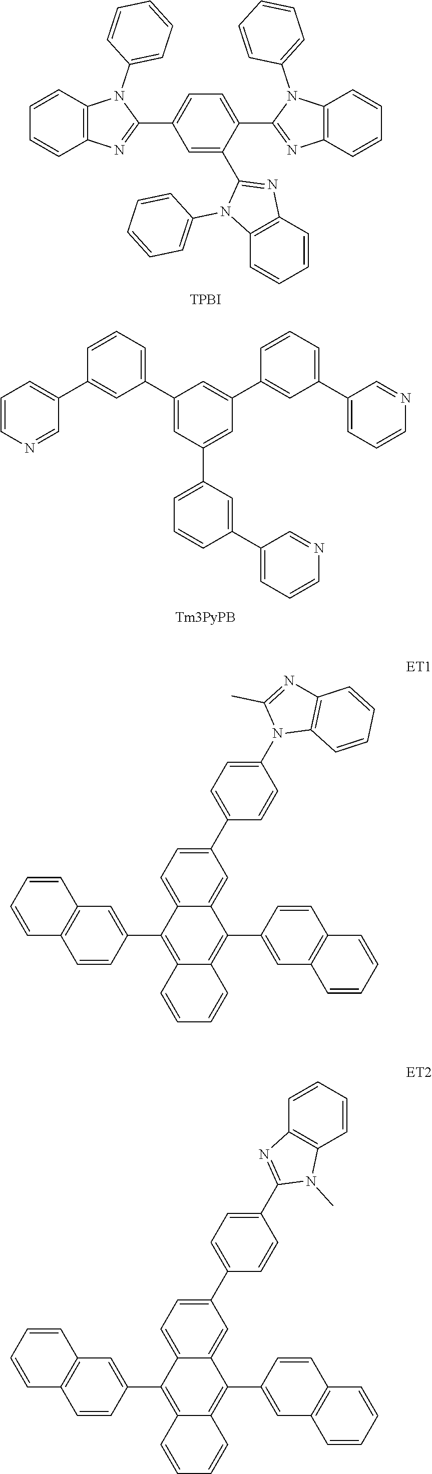

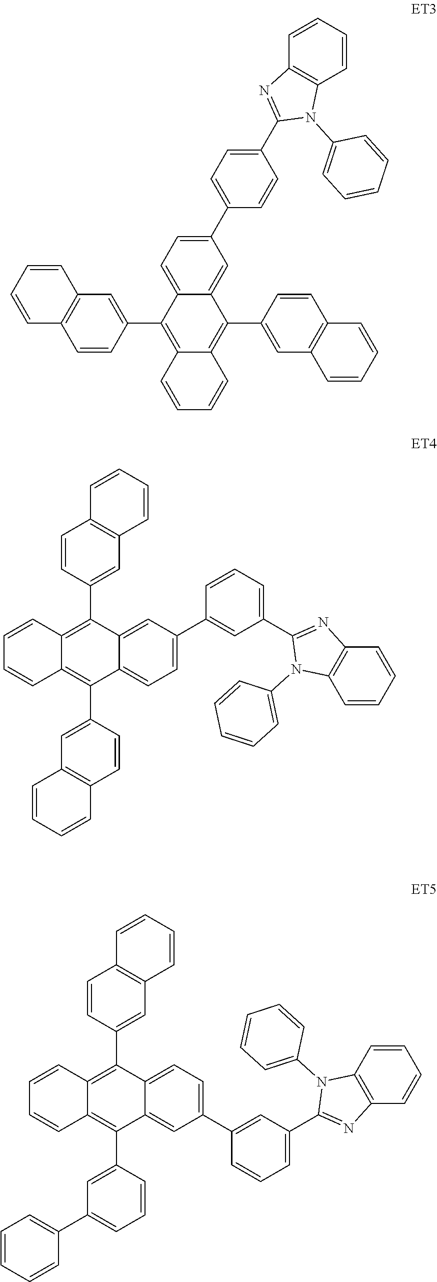 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-n2c(-c3cccc(-c4ccc5c(-c6ccc7ccccc7c6)c6ccccc6c(-c6ccc7ccccc7c6)c5c4)c3)nc3ccccc32)cc1 ; c1ccc(-c2cccc(-c3c4ccccc4c(-c4ccc5ccccc5c4)c4ccc(-c5cccc(-c6nc7ccccc7n6-c6ccccc6)c5)cc34)c2)cc1]

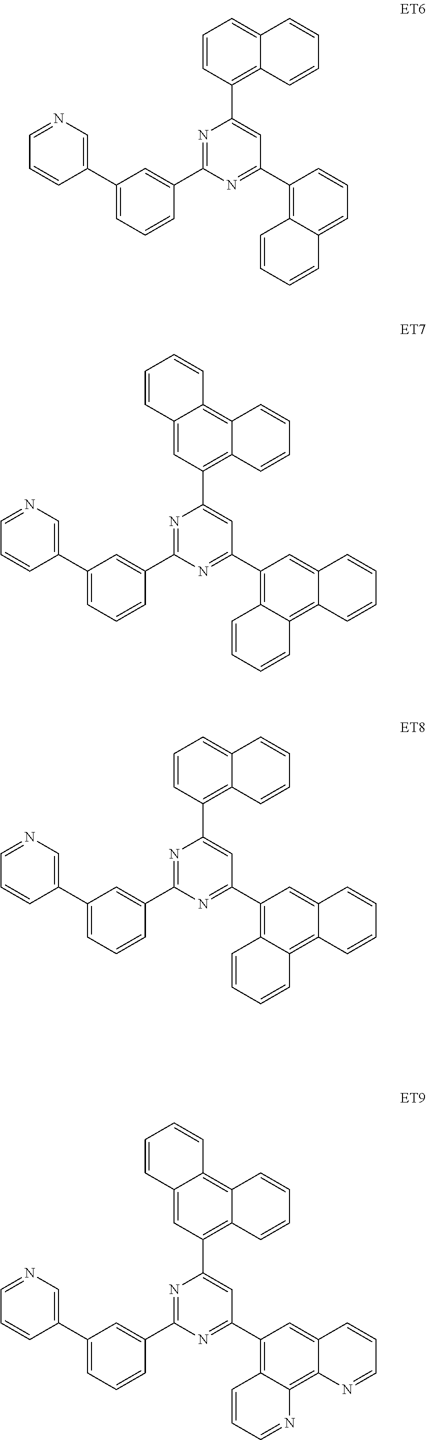 [SMILES: c1cncc(-c2cccc(-c3nc(-c4cccc5ccccc45)cc(-c4cccc5ccccc45)n3)c2)c1 ; c1cncc(-c2cccc(-c3nc(-c4cc5ccccc5c5ccccc45)cc(-c4cc5ccccc5c5ccccc45)n3)c2)c1 ; c1cncc(-c2cccc(-c3nc(-c4cccc5ccccc45)cc(-c4cc5ccccc5c5ccccc45)n3)c2)c1 ; c1cncc(-c2cccc(-c3nc(-c4cc5ccccc5c5ccccc45)cc(-c4cc5cccnc5c5ncccc45)n3)c2)c1]

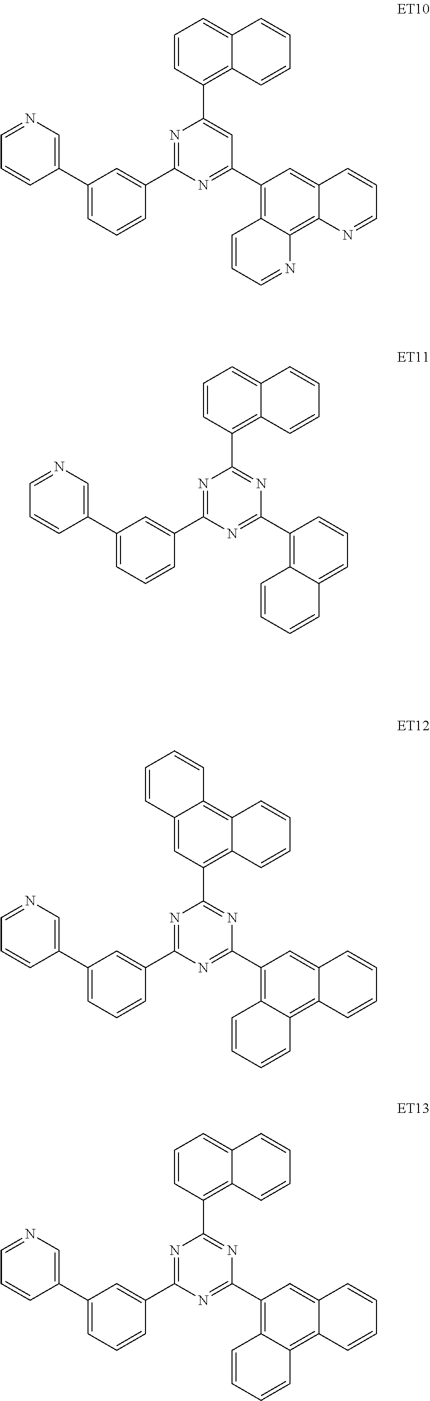 [SMILES: c1cncc(-c2cccc(-c3nc(-c4cccc5ccccc45)cc(-c4cc5cccnc5c5ncccc45)n3)c2)c1 ; c1cncc(-c2cccc(-c3nc(-c4cccc5ccccc45)nc(-c4cccc5ccccc45)n3)c2)c1 ; c1cncc(-c2cccc(-c3nc(-c4cc5ccccc5c5ccccc45)nc(-c4cc5ccccc5c5ccccc45)n3)c2)c1 ; c1cncc(-c2cccc(-c3nc(-c4cccc5ccccc45)nc(-c4cc5ccccc5c5ccccc45)n3)c2)c1]

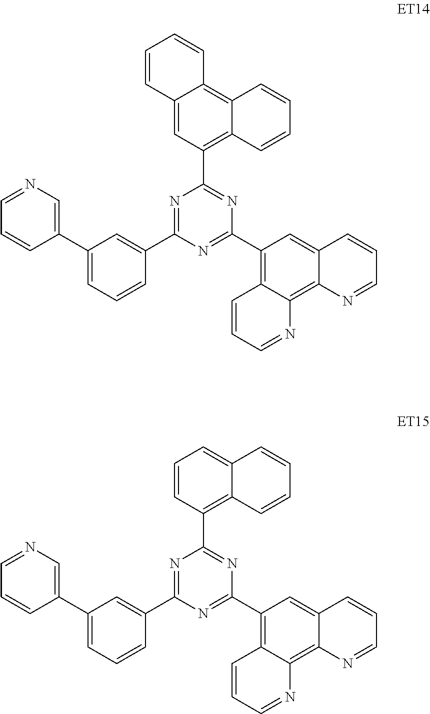 [SMILES: c1cncc(-c2cccc(-c3nc(-c4cc5ccccc5c5ccccc45)nc(-c4cc5cccnc5c5ncccc45)n3)c2)c1 ; c1cncc(-c2cccc(-c3nc(-c4cccc5ccccc45)nc(-c4cc5cccnc5c5ncccc45)n3)c2)c1]

In some embodiments, the electron mobility of the first n-type charge-generating layer 105a is greater than or equal to 10⁻⁵ cm²/Vs, the electron mobility of the first buffer layer 104 is less than 10⁻³ cm²/Vs, and the electron mobility of the second buffer layer 106 is less than 10⁻³ cm²/Vs. For example, the electron mobility of the first buffer layer 104 or the electron mobility of the second buffer layer 106 may be 2×10⁻⁵ cm²/Vs, 4×10⁻⁵ cm²/Vs, 5×10⁻⁵ cm²/Vs, 10⁻⁴ cm²/Vs, 2×10⁻⁴ cm²/Vs, 4×10⁻⁴ cm²/Vs, 5×10⁻⁴ cm²/Vs, 6×10⁻⁴ cm²/Vs, 8×10⁻⁴ cm²/Vs, or the like. By setting the second buffer layer 106, the sensitivity of reverse charges generated by the direct contact between the first n-type charge-generating layer 105a and the first p-type charge-generating layer 105b can be improved, thereby improving the operation stability of the display panel 10 at high temperature.

Preferably, the electron mobility of the first electron transport layer 112 is greater than 10⁻⁵ cm²/Vs and less than 10⁻³ cm²/Vs, and the electron mobility of the first buffer layer 104 is greater than 10⁻⁵ cm²/Vs, and can be, for example, 2×10⁻⁵ cm²/Vs, 4×10⁻⁵ cm²/Vs, 5×10⁻⁵ cm²/Vs, 10⁻⁴ cm²/Vs, 2×10⁻⁴ cm²/Vs, 4×10⁻⁴ cm²/Vs, 5×10⁻⁴ cm²/Vs, 6×10⁻⁴ cm²/Vs, 8×10⁻⁴ cm²/Vs, or the like. A layer in the first electron transport sub-layer 112 that is in direct contact with the first buffer layer 104 may be the first electron transport sub-layer. By designing the range of the electron mobility of the first buffer layer 104 being the same as the range of the electron mobility of the first electron transport sub-layer, it is conducive to preventing the setting of the first buffer layer 104 from reducing the mobility of electrons from the first n-type charge-generating layer 105a to the first light-emitting unit 109.

In some embodiments, the material of the second buffer layer 106 is the same as the material of the first buffer layer 104, which is conducive to simplifying manufacturing processes of the first buffer layer 104 and the second buffer layer 106 and facilitating the production of the display panel 10.

The evaporation process is used to form the first buffer layer 104, the second buffer layer 106, and the first n-type charge-generating layer 105a. When only the second buffer layer 106 is present, even if the material of the second buffer layer 106 is the same as the first electron transport material, it is still necessary to add an evaporation period for individually evaporating the first electron transport material after an evaporation period of the original evaporation process for forming the first n-type charge-generating layer 105a, so as to form the second buffer layer 106 disposed between the first n-type charge-generating layer 105a and the first p-type charge-generating layer 105b, which is a complex process. When the material of the first buffer layer 104 and the material of the second buffer layer 106 are the same, which are different from the first electron transport material of the first n-type charge-generating layer 105a, it is necessary to add an evaporation chamber to form the first buffer layer 104 and the second buffer layer 106, which makes the process more complex and costly. When the material of the first buffer layer 104, the material of the second buffer layer 106, and the first electron transport material of the first n-type charge-generating layer 105a are the same, it is possible to change complete co-evaporation of the original first electron transport material and the first charge doped material to incomplete co-evaporation in a period of the original evaporation process for forming the first n-type charge-generating layer 105a: a part of the first electron transport material that is evaporated first forms one of the first buffer layer 104 and the second buffer layer 106, then, the first electron transport material and the first charge doped material are co-evaporated to form the first n-type charge-generating layer 105a, and a part of the first electron transport material that is finally evaporated forms the other of the first buffer layer 104 and the second buffer layer 106, which achieves the formation of the first buffer layer 104, the second buffer layer 106, and the first n-type charge-generating layer 105a in the same evaporation chamber without increasing the evaporation period, and is conducive to simplifying the manufacturing process. Therefore, the material of the second buffer layer 106, the material of the first buffer layer 104, and the first electron transfer material are preferably the same, so that only the incomplete co-evaporation of the first electron transfer material and the first charge doped material is required to form the second buffer layer 106 and the first buffer layer 104 in a evaporation period for forming the first n-type charge-generating layer 105a, which further simplifies the process and facilitates the production of the display panel 10.

When the material of the second buffer layer 106, the material of the first buffer layer 104, and the first electron transport material are the same, a difference between a thickness of the second buffer layer 106 and a thickness of the first buffer layer 104 is greater than or equal to 0 angstrom and less than or equal to 50 angstroms, for example, 5 angstroms, 10 angstroms, 15 angstroms, 20 angstroms, 25 angstroms, 30 angstroms, 35 angstroms, 40 angstroms, 45 angstroms, or the like. Preferably, the difference between the thickness of the second buffer layer 106 and the thickness of the first buffer layer 104 is 0 angstrom, that is, the thickness of the second buffer layer 106 is the same as the thickness of the first buffer layer 104.

When the material of the second buffer layer 106 is the same as the material of the first buffer layer 104, the range of the electron mobility of the second buffer layer 106 is the same as the range of the electron mobility of the first buffer layer 104. That is, the electron mobility of the second buffer layer 106 is greater than 10⁻⁵ cm²/Vs and less than 10⁻³ cm²/Vs. For example, it may be 2×10⁻⁵ cm²/Vs, 4×10⁻⁵ cm²/Vs, 5×10⁻⁵ cm²/Vs, 10⁻⁴ cm²/Vs, 2×10⁻⁴ cm²/Vs, 4×10⁻⁴ cm²/Vs, 5×10⁻⁴ cm²/Vs, 6×10⁻⁴ cm²/Vs, 8×10⁻⁴ cm²/Vs, or the like.

In some embodiments, a difference between the highest occupied molecular orbital energy level of the first buffer layer 104 and the lowest unoccupied molecular orbital energy level of the first n-type charge-generating layer 105a is greater than 2 eV and less than 4 eV. For example, it may be 2.2 eV, 2.5 eV, 2.7 eV, 3 eV, 3.2 eV, 3.4 eV 3.5 eV, 3.6 eV, 3.8 eV, or the like. By maintaining the difference between energy levels of the first buffer layer 104 and the first n-type charge-generating layer 105a within an appropriate range, it is conducive to the transmitting of electrons from the first n-type charge-generating layer 105a to the first light-emitting unit 109 through the first buffer layer 104. A difference between the highest occupied molecular orbital energy level of the second buffer layer 106 and the lowest unoccupied molecular orbital energy level of the first n-type charge-generating layer 105a is greater than 2 eV and less than 4 eV. For example, it may be 2.2 eV, 2.5 eV, 2.7 eV, 3 eV, 3.2 eV, 3.4 eV, 3.5 eV, 3.6 eV, 3.8 eV, or the like, so as to facilitate electrons generated by the first p-type charge-generating layer 105b being easily transmitted to the first n-type charge-generating layer 105a through the second buffer layer 106.

In some embodiments, a difference between the highest occupied molecular orbital energy level of the first buffer layer 104 and the lowest unoccupied molecular orbital energy level of a layer in the first electron transport layer 112 that is in contact with the first buffer layer 104 is less than or equal to 2 eV and greater than or equal to 4 eV. For example, it may be 2.2 eV, 2.5 eV, 2.7 eV, 3 eV, 3.2 eV, 3.4 eV, 3.5 eV, 3.6 eV, 3.8 eV, or the like, making it easier for electrons to be transmitted from the first buffer layer 104 to the first electron transport layer 112.

In some embodiments, a difference between an absolute value of the lowest unoccupied molecular orbital energy level of the first n-type charge-generating layer 105a and an absolute value of the highest occupied molecular orbital energy level of the first p-type charge-generating layer 105b is less than or equal to 3.5 eV. For example, it may be 1 eV, 1.5 eV, 2 eV, 2.5 eV, 3 eV, or the like, which facilitates electrons being transmitted from the first p-type charge-generating layer 105b to the first n-type charge-generating layer 105a.

In some embodiments, the absolute value of the lowest unoccupied molecular orbital energy level of the first n-type charge-generating layer 105a is greater than or equal to 2.5 eV and less than or equal to 4.5 eV. For example, it may be 2.8 eV, 3 eV, 3.2 eV, 3.5 eV, 3.6 eV, 3.8 eV, 4 eV, 4.2 eV, or the like.

In some embodiments, the absolute value of the highest occupied molecular orbital energy level of the first p-type charge-generating layer 105b is greater than or equal to 4.5 eV and less than or equal to 6.5 eV. For example, it may be 4.8 eV, 5 eV, 5.2 eV, 5.5 eV, 5.6 eV, 5.8 eV, 6 eV, 6.2 eV, or the like.

In some embodiments, an electron work function of the first buffer layer 104 is between an electron work function of the first n-type charge-generating layer 105a and an electron work function of the first p-type charge-generating layer 105b, and an electron work function of the second buffer layer 106 is between the electron work function of the first n-type charge-generating layer 105a and the electron work function of the first p-type charge-generating layer 105b.

In some embodiments, the electron work function of the first buffer layer 104 is greater than 5.5 eV and less than 7.5 eV. For example, it may be 6 eV, 6.2 eV, 6.5 eV, 6.7 eV, 7 eV, 7.2 eV, or the like.

In some embodiments, the electron work function of the first electron transport layer 112 is greater than 5.5 eV and less than 7.5 eV. The electron work function of the first buffer layer 104 being controlled within the same range as the electron work function of the first electron transport layer 112, facilitates reducing the interference of the setting of the first buffer layer 104 on the movement of electrons.

In some embodiments, the electron work function of the second buffer layer 106 is greater than 5.5 eV and less than 7.5 eV. For example, it may be 6 eV, 6.2 eV, 6.5 eV, 6.7 eV, 7 eV, 7.2 eV, or the like.

The first p-type charge-generating layer 105b includes a first hole transport material, and the third buffer layer 115 includes a second hole transport material.

In some embodiments, the first hole transport material and the second hole transport material are selected from at least one of derivatives of aniline, derivatives of diphenylamine, derivatives of triphenylamine, derivatives of carbazole, derivatives of furan, and derivatives of thiophene.

In some embodiments, the first hole transport material and the second hole transport material are independently selected from a compound having a structure represented by any one of the following formula (5-1) to formula (5-4):

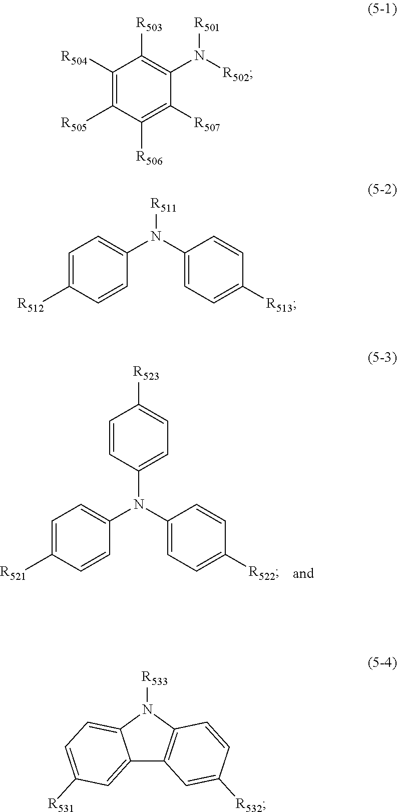

in which R₅₀₁ to R₅₀₇, R₅₁₁ to R₅₁₃, R₅₂₁ to R₅₂₃, and R₅₁₁ to R₅₃₃ are independently selected from hydrogen, deuterium, a substituted or unsubstituted cycloalkyl group having 3 to 10 carbon atoms, a substituted or unsubstituted heterocyclic alkyl group having 1 to 10 carbon atoms, a substituted or unsubstituted cycloalkenyl group having 3 to 10 carbon atoms, a substituted or unsubstituted heterocyclic alkenyl group having 1 to 10 carbon atoms, a substituted or unsubstituted aryl group having 6 to 60 carbon atoms, a substituted or unsubstituted aryloxy group having 6 to 60 carbon atoms, a substituted or unsubstituted aryl thiol group having 6 to 60 carbon atoms, a substituted or unsubstituted heteroaryl group having 5 to 60 carbon atoms, a substituted or unsubstituted non-aromatic fused polycyclic group, or a substituted or unsubstituted non-aromatic fused heteropolycyclic group.

The third buffer layer 115 is in direct contact with the second hole transport sub-layer of the second hole transport layer 113.

A selection range of a material of the second hole transport sub-layer may be the same as or different from selection ranges of the first hole transport material and the second hole transport material.

In some embodiments, the material of the second hole transport sub-layer, the first hole transport material, and the second hole transport material are independently selected from one or more of the following compounds:

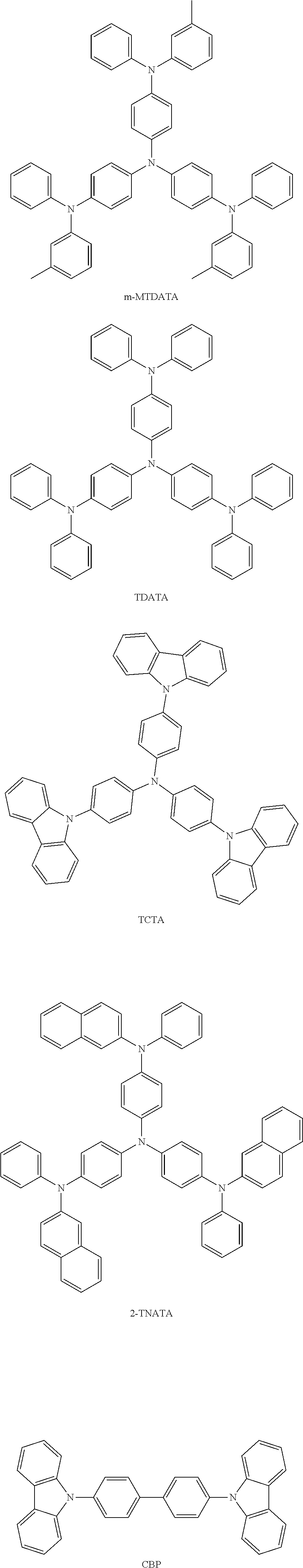

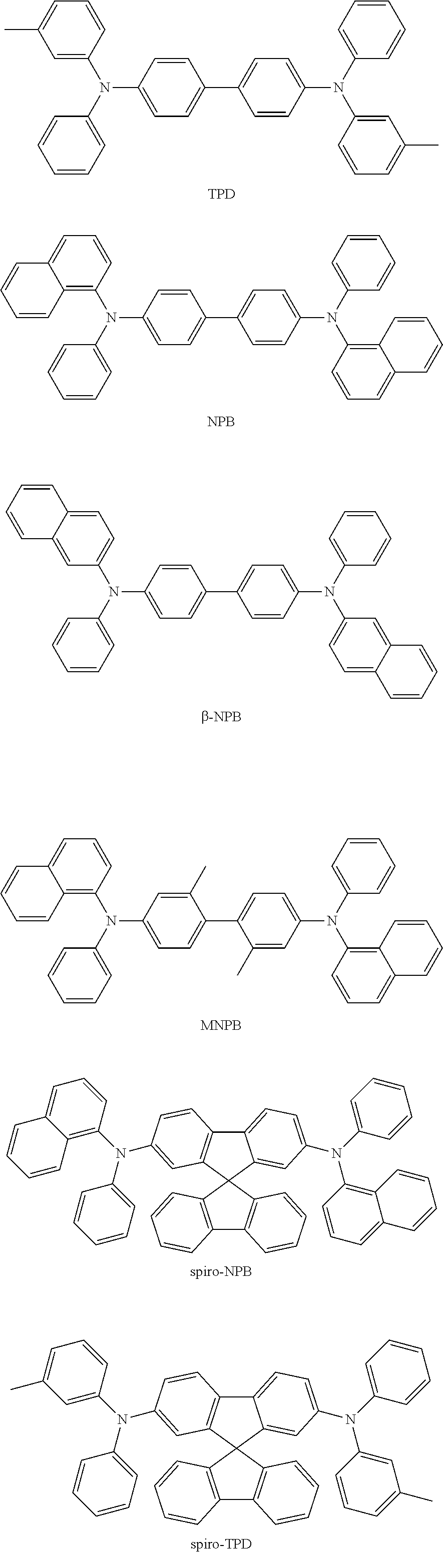

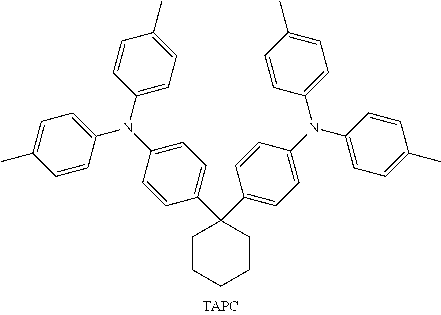

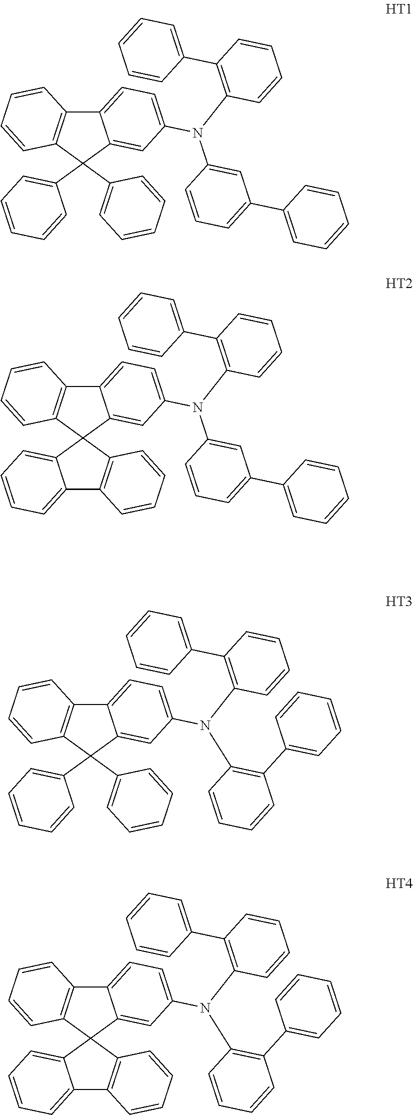 [SMILES: c1ccc(-c2cccc(N(c3ccc4c(c3)C(c3ccccc3)(c3ccccc3)c3ccccc3-4)c3ccccc3-c3ccccc3)c2)cc1 ; c1ccc(-c2cccc(N(c3ccc4c(c3)C3(c5ccccc5-c5ccccc53)c3ccccc3-4)c3ccccc3-c3ccccc3)c2)cc1 ; c1ccc(-c2ccccc2N(c2ccc3c(c2)C(c2ccccc2)(c2ccccc2)c2ccccc2-3)c2ccccc2-c2ccccc2)cc1 ; c1ccc(-c2ccccc2N(c2ccc3c(c2)C2(c4ccccc4-c4ccccc42)c2ccccc2-3)c2ccccc2-c2ccccc2)cc1]

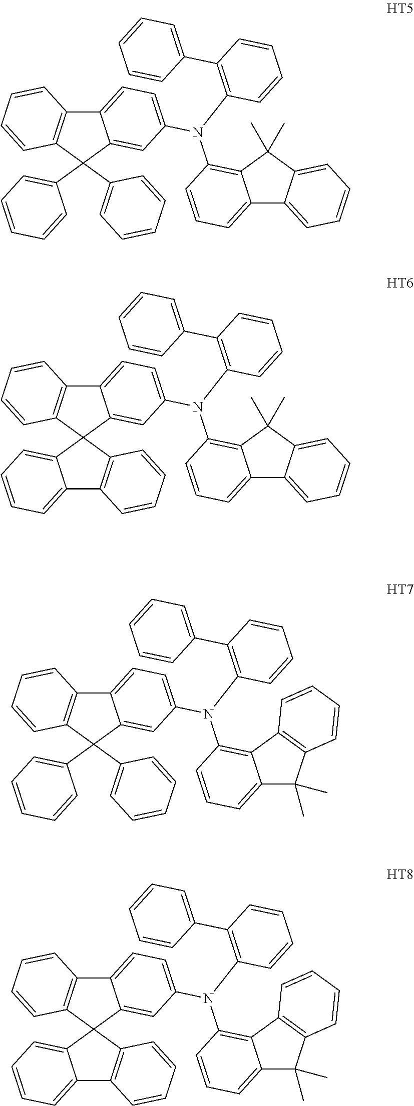 [SMILES: CC1(C)c2ccccc2-c2cccc(N(c3ccc4c(c3)C(c3ccccc3)(c3ccccc3)c3ccccc3-4)c3ccccc3-c3ccccc3)c21 ; CC1(C)c2ccccc2-c2cccc(N(c3ccc4c(c3)C3(c5ccccc5-c5ccccc53)c3ccccc3-4)c3ccccc3-c3ccccc3)c21 ; CC1(C)c2ccccc2-c2c(N(c3ccc4c(c3)C(c3ccccc3)(c3ccccc3)c3ccccc3-4)c3ccccc3-c3ccccc3)cccc21 ; CC1(C)c2ccccc2-c2c(N(c3ccc4c(c3)C3(c5ccccc5-c5ccccc53)c3ccccc3-4)c3ccccc3-c3ccccc3)cccc21]

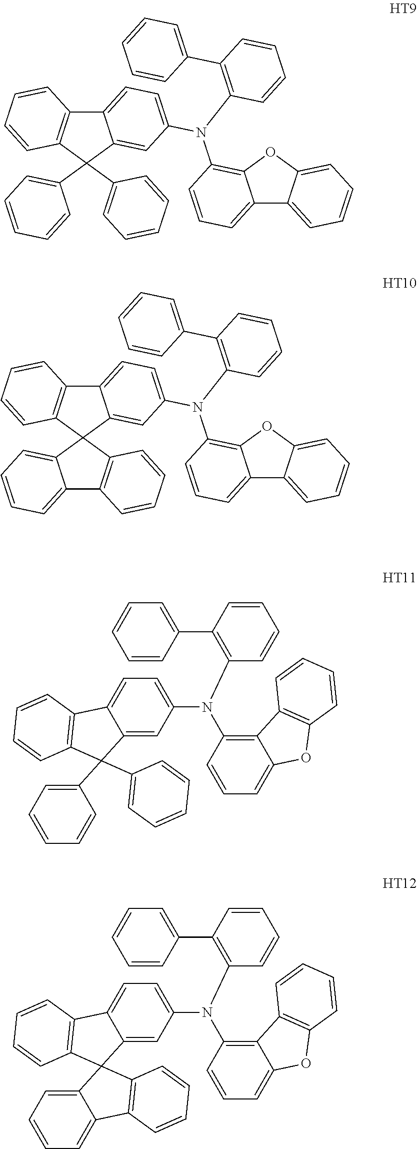 [SMILES: c1ccc(-c2ccccc2N(c2ccc3c(c2)C(c2ccccc2)(c2ccccc2)c2ccccc2-3)c2cccc3c2oc2ccccc23)cc1 ; c1ccc(-c2ccccc2N(c2ccc3c(c2)C2(c4ccccc4-c4ccccc42)c2ccccc2-3)c2cccc3c2oc2ccccc23)cc1 ; c1ccc(-c2ccccc2N(c2ccc3c(c2)C(c2ccccc2)(c2ccccc2)c2ccccc2-3)c2cccc3oc4ccccc4c23)cc1 ; c1ccc(-c2ccccc2N(c2ccc3c(c2)C2(c4ccccc4-c4ccccc42)c2ccccc2-3)c2cccc3oc4ccccc4c23)cc1]

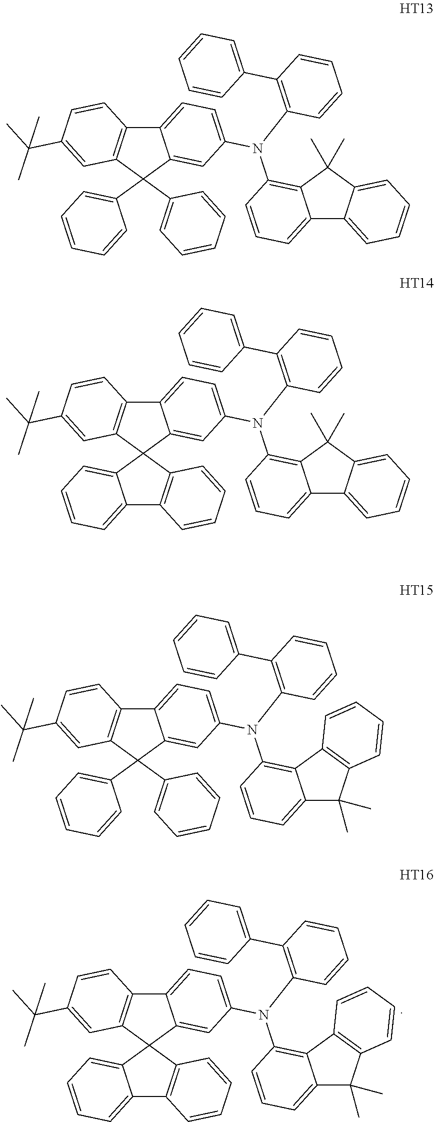 [SMILES: CC(C)(C)c1ccc2c(c1)C(c1ccccc1)(c1ccccc1)c1cc(N(c3ccccc3-c3ccccc3)c3cccc4c3C(C)(C)c3ccccc3-4)ccc1-2 ; CC(C)(C)c1ccc2c(c1)C1(c3ccccc3-c3ccccc31)c1cc(N(c3ccccc3-c3ccccc3)c3cccc4c3C(C)(C)c3ccccc3-4)ccc1-2 ; CC(C)(C)c1ccc2c(c1)C(c1ccccc1)(c1ccccc1)c1cc(N(c3ccccc3-c3ccccc3)c3cccc4c3-c3ccccc3C4(C)C)ccc1-2 ; CC(C)(C)c1ccc2c(c1)C1(c3ccccc3-c3ccccc31)c1cc(N(c3ccccc3-c3ccccc3)c3cccc4c3-c3ccccc3C4(C)C)ccc1-2]

In some embodiments, the third buffer layer 115 is composed of the second hole transport material that is the same as the first hole transport material.

In some embodiments, the fourth buffer layer 116 is composed of the second hole transport material.

In some embodiments, the composition of the material of the third buffer layer 115 and the composition of the material of the fourth buffer layer 116 are the same, and both are the same as the composition of the first hole transport material.

In some embodiments, the first p-type charge-generating layer 105b also includes a second charge doped material. The first p-type charge-generating layer 105b may be composed of the second hole transport material and the second charge doped material. The addition of the second charge doped material is beneficial to improve the hole mobility of the first p-type charge-generating layer 105b. Preferably, a mass ratio of the second hole transport material to the second charge doped material ranges from 99:1 to 80:20. For example, it may be 98:2, 95:5, 92:8, 90:10, 88:12, 85:15, 82:18, or the like.

In some embodiments, the second charge doped material may be selected from at least one of a derivative of quinone, a metal oxide, and a compound containing a cyano group.

In some embodiments, the second charge doped material may be selected from at least one of tetracyanoquinone dimethane (TCNQ), 2,3,5,6-tetrafluoro-7,7,8,8-tetracyanoquinone dimethane (F4-TCNQ), tungsten oxide, molybdenum oxide, and 1,4,5,8,9,12-hexaazatriphenylene hexanitrile (HAT-CN).

In some embodiments, the second charge doped material is selected from a compound represented by any one of the following formula (6-1) to formula (6-3):

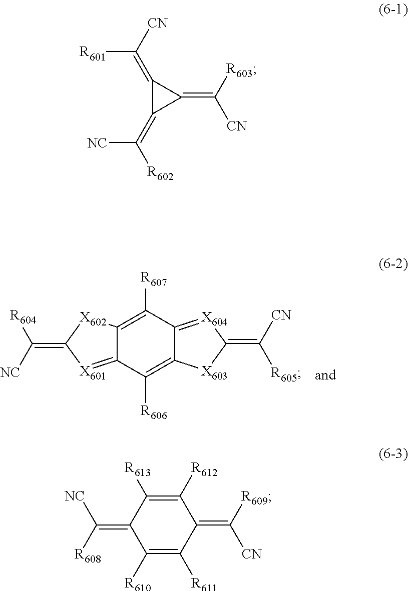

in which X₆₀₁ to X₆₀₃ are independently selected from C, O, or N;

R₆₀₀ to R₆₁₃ are independently selected from a substituted or unsubstituted cycloalkyl group having 3 to 10 carbon atoms, a substituted or unsubstituted heterocyclic alkyl group having 1 to 10 carbon atoms, a substituted or unsubstituted cycloalkenyl group having 3 to 10 carbon atoms, a substituted or unsubstituted heterocyclic alkenyl group having 1 to 10 carbon atoms, a substituted or unsubstituted aryl group having 6 to 60 carbon atoms, a substituted or unsubstituted heteroaryl group having 5 to 60 carbon atoms, a substituted or unsubstituted non-aromatic fused polycyclic group, a substituted or unsubstituted non-aromatic fused heterocyclic group, a cyano group, —F, —Cl, —Br, —I, or an alkyl group having 1 to 20 carbon atoms and substituted by —F, —Cl, —Br, —I.

In some embodiments, the hole mobility of the first p-type charge-generating layer 105b is greater than or equal to 10⁻² cm²/Vs, the hole mobility of the third buffer layer 115 is greater than 10⁻⁴ cm²/Vs, and the hole mobility of the fourth buffer layer 116 is less than 10⁻⁴ cm²/Vs. By setting the third buffer layer 115 and the fourth buffer layer 116, the sensitivity of reverse charges generated by the direct contact between the first n-type charge-generating layer 105a and the first p-type charge-generating layer 105b can be further improved, thereby improving the operation stability of the display panel 10 at high temperature.

Preferably, the hole mobility of the second hole transport layer 113 is greater than 10⁻⁴ cm²/Vs and less than 10⁻² cm²/Vs, and the hole mobility of the third buffer layer 115 is greater than 10⁻⁴ cm²/Vs. For example, the hole mobility of the third buffer layer 115 may be 2×10⁻⁴ cm²/Vs, 4×10⁻⁴ cm²/Vs, 5×10⁻⁴ cm²/Vs, 10⁻³ cm²/Vs, 2×10⁻³ cm²/Vs, 4×10⁻³ cm²/Vs, 5×10⁻³ cm²/Vs, 6×10⁻³ cm²/Vs, 8×10⁻³ cm²/Vs, or the like. A layer in the second hole transport layer 113 that is in direct contact with the third buffer layer 115 may be the second hole transport sub-layer. By designing the range of the hole mobility of the third buffer layer 115 being the same as the range of the hole mobility of the second hole transport sub-layer, it is conducive to preventing the setting of the third buffer layer 115 from reducing the mobility of holes from the first p-type charge-generating layer 105b to the second light-emitting unit 110.

In some embodiments, the material of the fourth buffer layer 116 is the same as the material of the third buffer layer 115, which is conducive to simplifying manufacturing processes of the fourth buffer layer 116 and the third buffer layer 115, and facilitating the production of the display panel 10.

The evaporation process is used to form the fourth buffer layer 116, the third buffer layer 115, and the first p-type charge-generating layer 105b. When only the fourth buffer layer 116 is present, even if the material of the fourth buffer layer 116 is the same as the first hole transport material, it is still necessary to add an evaporation period for individually evaporating the first hole transport material after an evaporation period of the original evaporation process for forming the first p-type charge-generating layer 105b, so as to form the fourth buffer layer 116 disposed between the first n-type charge-generating layer 105a and the first p-type charge-generating layer 105b, which is a complex process. When the material of the fourth buffer layer 116 and the material of the third buffer layer 115 are the same, which are different from the first hole transport material of the first p-type charge-generating layer 105b, it is necessary to add an evaporation chamber to form the fourth buffer layer 116 and the third buffer layer 115, which makes the process more complex and costly. When the material of the fourth buffer layer 116, the material of the third buffer layer 115, and the first hole transport material of the first p-type charge-generating layer 105b are the same, it is possible to change complete co-evaporation of the original first hole transport material and the second charge doped material to incomplete co-evaporation in a period of the original evaporation process for forming the first p-type charge-generating layer 105b: a part of the first hole transport material that is evaporated first forms one of the fourth buffer layer 116 and the third buffer layer 115, then, the first hole transport material and the second charge doped material are co-evaporated to form the first p-type charge-generating layer 105b, and a part of the first hole transport material that is finally evaporated forms the other of the fourth buffer layer 116 and the third buffer layer 115, which achieves the formation of the fourth buffer layer 116, third buffer layer 115, and the first p-type charge-generating layer 105b in the same evaporation chamber without increasing the evaporation period, and is conducive to simplifying the manufacturing process. Therefore, it is preferred that the material of the fourth buffer layer 116, the material of the third buffer layer 115, and the first hole transport material are the same, so that only the incomplete co-evaporation of the second hole transport material and the second charge doped material is required to form the fourth buffer layer 116 and the third buffer layer 115 in a evaporation period for forming the first p-type charge-generating layer 105b, which further simplifies the process and facilitates the production of the display panel 10.

When the material of the fourth buffer layer 116, the material of the third buffer layer 115, and the first hole transport material are the same, a difference between a thickness of the fourth buffer layer 116 and a thickness of the third buffer layer 115 is greater than or equal to 0 angstrom and less than or equal to 50 angstroms. For example, it may be 5 angstroms, 10 angstroms, 15 angstroms, 20 angstroms, 25 angstroms, 30 angstroms, 35 angstroms, 40 angstroms, 45 angstroms, or the like. Preferably, the difference between the thickness of the fourth buffer layer 116 and the thickness of the third buffer layer 115 is 0 angstrom, that is, the thickness of the fourth buffer layer 116 is the same as the thickness of the third buffer layer 115.

When the material of the fourth buffer layer 116 is the same as the material of the third buffer layer 115, the range of the hole mobility of the fourth buffer layer 116 is the same as the range of the hole mobility of the third buffer layer 115. That is, the hole mobility of the fourth buffer layer 116 is greater than 10⁻⁴ cm²/Vs and less than 10⁻² cm²/Vs. For example, it may be 2×10⁻⁴ cm²/Vs, 4×10⁻⁴ cm²/Vs, 5×10⁻⁴ cm²/Vs, 10⁻³ cm²/Vs, 2×10⁻³ cm²/Vs, 4×10⁻³ cm²/Vs, 5×10⁻³ cm²/Vs, 6×10⁻³ cm²/Vs, 8×10⁻³ cm²/Vs, or the like.

In some embodiments, the electron mobilities of the first buffer layer 104, the second buffer layer 106, a layer in the first electron transport layer 112 that is in direct contact with the first buffer layer 104, and the first n-type charge-generating layer 105a, and the hole mobilities of the first p-type charge-generating layer 105b, the third buffer layer 115, the fourth buffer layer 116, and a layer in the second hole transport layer 113 that is in direct contact with the third buffer layer 115 may be obtained through the space-charge-limited-current (SCLC) test. Specifically, the test results are combined with the Mott-Gurney equation

$$“ J = \frac{9}{8} {ε}_{0} {ε}_{r} {μ}_{0} \frac{{E}^{2}}{L} exp ( γ \sqrt{E} ) ”$$

and Frenkel effect, taking the logarithm of both ends of the above-mentioned equation to obtain the following equation:

$$ln ( \frac{J}{{E}^{2}} ) = ln ( \frac{9}{8} \frac{{ε}_{r} {ε}_{0} {μ}_{0}}{L} ) + γ \sqrt{E} ,$$

in which J indicates current density, εᵣ indicates the relative dielectric constant of organic materials, εₒ indicates the vacuum dielectric constant, μₒ indicates the zero field mobility, E indicates electric intensity, L indicates a thickness of organic materials, and γ indicates Mott-Gurney constant. It can be seen that there is a linear relationship between

$$ln ( \frac{J}{{E}^{2}} )$$

and \sqrt{E}. The function graph of

$$ln ( \frac{J}{{E}^{2}} )$$

changing with \sqrt{E} is plotted, then the zero field mobility of charge carriers of organic materials is calculated based on the intercept of the straight line, and the field dependent mobility of the charge carriers under a fixed electric field can be obtained by introducing it into the Poole Frenkel equation.

In some embodiments, the difference between the lowest unoccupied molecular orbital energy level of the third buffer layer 115 and the highest occupied molecular orbital energy level of the first p-type charge-generating layer 105b is greater than 2 eV and less than 4 eV. For example, it may be 2.2 eV, 2.5 eV, 2.7 eV, 3 eV, 3.2 eV, 3.4 eV, 3.5 eV, 3.6 eV 3.8 eV, or the like, to facilitate maintaining an appropriate range of the difference between energy levels of the first p-type charge-generating layer 105b and the third buffer layer 115, which is conducive to the transmitting of electrons from the third buffer layer 115 to the first p-type charge-generating layer 105b, and correspondingly, the transmitting of holes from the first p-type charge-generating layer 105b to the third buffer layer 115. The difference between the lowest unoccupied molecular orbital energy level of the fourth buffer layer 116 and the highest occupied molecular orbital energy level of the first p-type charge-generating layer 105b is greater than 2 eV and less than 4 eV. For example, it may be 2.2 eV, 2.5 eV, 2.7 eV, 3 eV, 3.2 eV, 3.4 eV, 3.5 eV, 3.6 eV, 3.8 eV, or the like, to facilitate the transmitting of electrons from the first p-type charge-generating layer 105b to the first n-type charge-generating layer 105a through the fourth buffer layer 116.

In some embodiments, a difference between the lowest unoccupied molecular orbital energy level of the third buffer layer 115 and the highest occupied molecular orbital energy level of a layer in the second hole transport layer 113 that is in direct contact with the third buffer layer 115 is greater than or equal to 2 eV and less than or equal to 4 eV. For example, it may be 2.2 eV, 2.5 eV, 2.7 eV, 3 eV, 3.2 eV, 3.4 eV, 3.5 eV, 3.6 eV, 3.8 eV, or the like, to facilitate the transmitting of electrons from the second hole transport layer 113 to the third buffer layer 115, and correspondingly, the transmitting of holes from the third buffer layer 115 to the second hole transport layer 113.

In some embodiments, the lowest unoccupied molecular orbital energy levels and the highest occupied molecular orbital energy levels of the first buffer layer 104, the second buffer layer 106, the third buffer layer 115, the fourth buffer layer 116, the first n-type charge-generating layer 105a, the first p-type charge-generating layer 105b, a layer in the first electron transport layer 112 that is in direct contact with the first buffer layer 104, and a layer in the second hole transport layer 113 that is in direct contact with the third buffer layer 115, can be obtained through an electrochemical method (such as electrochemical cyclic voltammetry), an ultraviolet photoelectron spectroscopy method, or the like. It can be understood that, the differences between the lowest unoccupied molecular orbital energy levels and the highest occupied molecular orbital energy levels are obtained under the same experimental method and conditions.

In some embodiments, an electron work function of the third buffer layer 115 is greater than 5.5 eV and less than 7.5 eV. For example, it may be 6 eV, 6.2 eV, 6.5 eV, 6.7 eV, 7 eV, 7.2 eV, or the like.

In some embodiments, an electron work function of the second hole transport layer 113 is greater than 5.5 eV and less than 7.5 eV. The electron work function of the third buffer layer 115 being controlled within the same range as the electron work function of the second hole transport layer 113, facilitates reducing the interference of the setting of the third buffer layer 115 on the movement of holes.

In some embodiments, the electron work function of the fourth buffer layer 116 is greater than 5.5 eV and less than 7.5 eV. For example, it may be 6 eV, 6.2 eV, 6.5 eV, 6.7 eV, 7 eV, 7.2 eV, or the like.

In some embodiments, the electron work functions of the first buffer layer 104, the second buffer layer 106, the first n-type charge-generating layer 105a, the first p-type charge-generating layer 105b, the first electron transport layer 112, the third buffer layer 115, the fourth buffer layer 116, and the second hole transport layer 113 can be obtained by measuring the photoelectron energy spectra of the aforementioned film layers, respectively, for example, obtained by methods such as X-ray photoelectron spectroscopy and/or ultraviolet photoelectron spectroscopy.

In some embodiments, the display panel 10 includes multiple light-emitting elements 100, which may emit red light, green light, and blue light, respectively.

Referring to FIG. 6, in some embodiments, the display panel 10 further includes an array substrate 200 disposed on a side of the light-emitting elements 100, and an encapsulation layer 300 disposed on a side of the light-emitting elements 100 away from the array substrate 200 and covering the light-emitting elements 100.

The display panel 10 further includes a polarizer layer 400 disposed on a side of the encapsulation layer 300 away from the light-emitting elements 100, and a cover layer 500 disposed on a side of the polarizer layer 400 away from the light-emitting elements 100. The polarizer layer 400 may be replaced by a color film layer, which may include multiple color resists and a black matrix disposed on two sides of each of the color resists.

The display panel 10 provided by the present disclosure, by setting the first buffer layer 104 and the second buffer layer 106 on opposite two sides of the first n-type charge-generating layer 105a, and both of the electron mobility of the first buffer layer 104 and the electron mobility of the second buffer layer 106 being less than the electron mobility of the first n-type charge-generating layer 105a, improves sensitivity of reverse charges generated by the direct contact between the first n-type charge-generating layer 105a and the first p-type charge-generating layer 105b. Moreover, the first buffer layer 104 and the second buffer layer 106 play a role in blocking holes between the first n-type charge-generating layer 105a and the first light-emitting layer 103, which improves the operation stability of the display panel 10 at high temperature.

Specific comparative examples of multiple groups of light-emitting elements will be described for explanation in the following.

### Example 1

### Light-Emitting Element 1

The light-emitting element 1 is formed by sequentially stacking a anode, a hole injection sub-layer, a hole transport sub-layer, an electron blocking sub-layer, a blue light-emitting layer, a hole blocking layer, an electron transport sub-layer, a first buffer layer, a first n-type charge-generating layer, a second buffer layer, a first p-type charge-generating layer, a hole transport sub-layer, an electron blocking sub-layer, a blue light-emitting layer, a hole blocking sub-layer, an electron transport sub-layer, an electron injection sub-layer, and a cathode.

A material of the anode is indium tin oxide, and the cathode is a mixed electrode of Mg and Ag, in which a mass ratio of Mg to Ag is 10:90.

A thickness of the electron injection sub-layer is 1 nm, and a material of the electron injection sub-layer is Yb.

A thickness of the electron transport sub-layer is 20 nm, and a material of the electron transport sub-layer is a mixture of ET5 and Liq, a mass ratio of ET5 to Liq is 50:50.

A thickness of the hole blocking sub-layer is 5 nm, and the material of the hole blocking sub-layer is ET6.

A thickness of the light-emitting layer is 20 nm, and a material of the light-emitting layer is a mixture of BH16 and BD3, a mass ratio of BH16 to BD3 is 98:2.

A thickness of the electron blocking sub-layer is 5 nm, and a material of the electron blocking sub-layer is TCTA.

A thickness of the hole transport sub-layer is 25 nm, and the material of the hole transport sub-layer is TAPC.

Both of a thickness of the first buffer layer and a thickness of the second buffer layer are 0.5 nm, and materials of the two are E19. Both of the electron mobility of the first buffer layer and the electron mobility of the second buffer layer are 3.0×10⁻⁴ cm²/Vs. Both of an electron work function of the first buffer layer and an electron work function of the second buffer layer are approximately 6.2 eV

The first n-type charge-generating layer is an n-type charge generation sub-layer with a thickness of 9 nm. A material of the n-type charge generation sub-layer is a mixture of E19 and Yb, in which Yb is a charge doped material, and a mass ratio of E19 to Yb is 98:2.

The first p-type charge-generating layer is a p-type charge generation sub-layer with a thickness of 10 nm. A material of the p-type charge generation sub-layer is a mixture of PD1 and TAPC, in which a mass ratio of TAPC to PD1 is 90:10.

A thickness of the hole injection sub-layer is 10 nm, and the material of the hole injection sub-layer is a mixture of TAPC and PD1, in which a mass ratio of TAPC to PD1 is 97:3.

### Example 2

### Light-Emitting Element 2

The formation of the light-emitting element 2 is the same as or similar to that of the light-emitting element 1, with the difference being that:

both of the thickness of the first buffer layer and the thickness of the second buffer layer are 1 nm, and the thickness of the first n-type charge-generating layer is 8 nm.

### Example 3

### Light-Emitting Element 3

The formation of the light-emitting element 3 is the same as or similar to that of the light-emitting element 1, with the difference being that:

both of the thickness of the first buffer layer and the thickness of the second buffer layer are 1.5 nm, and the thickness of the first n-type charge-generating layer is 7 nm.

### Example 4

### Light-Emitting Element 4

The formation of the light-emitting element 4 is the same as or similar to that of the light-emitting element 1, with the difference being that:

the light-emitting element 4 is formed by sequentially stacking an anode, a hole injection sub-layer, a hole transport sub-layer, an electron blocking sub-layer, a blue light-emitting layer, a hole blocking layer, an electron transport sub-layer, a first n-type charge-generating layer, a fourth buffer layer, a first p-type charge-generating layer, a third buffer layer, a hole transport sub-layer, an electron blocking sub-layer, a blue light-emitting layer, a hole blocking sub-layer, an electron transport sub-layer, an electron injection sub-layer, and a cathode.

A thickness of the first p-type charge-generating layer is 8 nm, and a material of the first p-type charge-generating layer is a mixture of PD1 and TAPC, in which a mass ratio of TAPC to PD1 is 90:10.

A thickness of the first n-type charge-generating layer is 10 nm, and a material of the first n-type charge-generating layer is a mixture of E19 and Yb, in which Yb is a charge doped material, and a mass ratio of E19 to Yb is 98:2.

Both of a thickness of the third buffer layer and a thickness of the fourth buffer layer are 1 nm, and materials of the two are TAPC. Both of the hole mobility of the third buffer layer and the hole mobility of the fourth buffer layer are 1.5×10⁻³ cm²/Vs. Both of an electron work function of the third buffer layer and an electron work function of the fourth buffer layer are approximately 5.5 eV.

### Example 5

### Light-Emitting Element 5

The formation of the light-emitting element 5 is the same as or similar to that of the light-emitting element 2, with the difference being that:

the light-emitting element 5 is formed by sequentially stacking an anode, a hole injection sub-layer, a hole transport sub-layer, an electron blocking sub-layer, a blue light-emitting layer, a hole blocking layer, an electron transport sub-layer, a first buffer layer, a first n-type charge-generating layer, a fourth buffer layer, a first p-type charge-generating layer, a third buffer layer, a hole transport sub-layer, an electron blocking sub-layer, a blue light-emitting layer, a hole blocking sub-layer, an electron transport sub-layer, an electron injection sub-layer, and a cathode.

A thickness of the first p-type charge-generating layer is 8 nm.

Both of a thickness of the third buffer layer and a thickness of the fourth buffer layer are 1 nm, and materials of the two are TAPC. Both of the hole mobility of the third buffer layer and the hole mobility of the fourth buffer layer are 1.5×10⁻³ cm²/Vs. Both of an electron work function of the third buffer layer and an electron work function of the fourth buffer layer are approximately 5.5 eV.

### Comparative Example 1

### Comparative Element 1

The formation of the comparative element 1 is the same as or similar to that of the light-emitting element 1, with the difference being that:

the comparative element 1 is formed by sequentially stacking an anode, a hole injection sub-layer, a hole transport sub-layer, an electron blocking sub-layer, a blue light-emitting layer, a hole blocking layer, an electron transport sub-layer, a first n-type charge-generating layer, a first p-type charge-generating layer, a hole transport sub-layer, an electron blocking sub-layer, a blue light-emitting layer, a hole blocking sub-layer, an electron transport sub-layer, an electron injection sub-layer, and a cathode.

A thickness of the first n-type charge-generating layer is 10 nm, the electron mobility of the first n-type charge-generating layer is 1.1×10⁻² cm²/Vs, an electron work function of the first n-type charge-generating layer is approximately 3.0 eV, a thickness of the first p-type charge-generating layer is 10 nm, the hole mobility of the first p-type charge-generating layer is 2.1×10⁻² cm²/Vs, and an electron work function of the first p-type charge-generating layer is approximately 5.2 eV

For the light-emitting elements 1-5 and the comparative element 1, driving voltages, current efficiency (CE), the time for the brightness to decrease to 95% of initial brightness under the same condition of the initial brightness (service life T95 under the same brightness), and shift of the driving voltages (voltage shift) recorded at the room temperature after 100 hours of illumination under the same current density (10 mA/cm²) and operating temperature (80° C.) are tested to obtain the results shown in table 1.

TABLE 1

| Device | Voltage(V) | CE (cd/A) | LT95 (hr) | Voltage shift (V) |
|---|---|---|---|---|
| Comparative | 6.45 | 8.95 | 89 | 0.78 |
| element 1 | | | | |
| Light-emitting | 6.48 | 8.89 | 87 | 0.15 |
| element 1 | | | | |
| Light-emitting | 6.51 | 8.91 | 85 | 0.14 |
| element 2 | | | | |
| Light-emitting | 6.55 | 8.92 | 87 | 0.15 |
| element 3 | | | | |
| Light-emitting | 6.49 | 8.94 | 90 | 0.12 |
| element 4 | | | | |
| Light-emitting | 6.49 | 8.96 | 92 | 0.10 |
| element 5 | | | | |

According to the results shown in table 1, it can be seen that, by setting the first and second buffer layers, the driving voltage drifts of the light-emitting elements under the operation of high-temperatures are effectively improved, while maintaining the current efficiency and the service life. Moreover, the setting of the third buffer layer and the fourth buffer layer further reduces the driving voltage drifts of the light-emitting elements under the operation of high-temperatures and improves the operation stability of the light-emitting elements, based on the improvement of the first second buffer layer and the second buffer layer.

The embodiments of the present disclosure provides the display panel, in which the light-emitting element includes the first electrode layer, the first light-emitting layer, the first buffer layer, the first charge-generating layer, the second buffer layer, the second light-emitting layer, and the second electrode layer; the first charge-generating layer includes the first n-type charge-generating layer and the first p-type charge-generating layer; both of the electron mobility of the first buffer layer and the electron mobility of the second buffer layer are less than the electron mobility of the first n-type charge-generating layer. The present disclosure, by setting the first buffer layer and the second buffer layer on opposite two sides of the first n-type charge-generating layer, and both of the electron mobility of the first buffer layer and the electron mobility of the second buffer layer being less than the electron mobility of the first n-type charge-generating layer, improves the sensitivity of reverse charges generated by the direct contact between the first n-type charge-generating layer and the first p-type charge-generating layer. Moreover, the first buffer layer and the second buffer layer play a role in blocking holes between the first n-type charge-generating layer and the first light-emitting layer, which improves the operation stability of display panels at high temperature.

It can be understood that for ordinary skilled in the art, equivalent substitutions or changes can be made based on the technical solutions and invention concepts of the present disclosure, and all these changes or substitutions should fall within the protection scope of the claims attached to the present disclosure.

What is claimed is:

1. A display panel, comprising:
a substrate;
a first electrode layer disposed on a side of the substrate;
a first light-emitting layer disposed on a side of the first electrode layer away from the substrate;
a first buffer layer disposed on a side of the first light-emitting layer away from the substrate;
a first charge-generating layer disposed on a side of the first buffer layer away from the substrate, wherein the first charge-generating layer comprises a first n-type charge-generating layer disposed on a side of the first buffer layer away from the substrate and a first p-type charge-generating layer disposed on a side of the first n-type charge-generating layer away from the substrate;
a second buffer layer disposed between the first n-type charge-generating layer and the first p-type charge-generating layer;
a second light-emitting layer disposed on a side of the first charge-generating layer away from the substrate; and
a second electrode layer disposed on a side of the second light-emitting layer away from the substrate;
wherein an electron mobility of the first buffer layer is less than an electron mobility of the first n-type charge-generating layer, and an electron mobility of the second buffer layer is less than the electron mobility of the first n-type charge-generating layer;
a difference between a highest occupied molecular orbital energy level of the first buffer layer and a lowest unoccupied molecular orbital energy level of the first n-type charge-generating layer is greater than 2 eV and less than 4 eV; and
a difference between a highest occupied molecular orbital energy level of the second buffer layer and the lowest unoccupied molecular orbital energy level of the first n-type charge-generating layer is greater than 2 eV and less than 4 eV.

2. The display panel of claim 1, wherein the display panel further comprises a first electron transport layer disposed between the first light-emitting layer and the first buffer layer, wherein a side of the first buffer layer close to the first n-type charge-generating layer is in contact with the first n-type charge-generating layer, and a side of the first buffer layer away from the first n-type charge-generating layer is in contact with the first electron transport layer; and
wherein a side of the second buffer layer close to the first n-type charge-generating layer is in contact with the first n-type charge-generating layer, and a side of the second buffer layer away from the first n-type charge-generating layer is in contact with the first p-type charge-generating layer.

3. The display panel of claim 2, wherein a difference between the highest occupied molecular orbital energy level of the first buffer layer and a lowest unoccupied molecular orbital energy level of the first electron transport layer is greater than 2 eV and less than 4 eV.

4. The display panel of claim 2, wherein the electron mobility of the first n-type charge-generating layer is greater than or equal to 10⁻⁴ cm²/Vs, the electron mobility of the first buffer layer is less than 10⁻⁴ cm²/Vs, and the electron mobility of the second buffer layer is less than 10⁻⁴ cm²/Vs.

5. The display panel of claim 4, wherein an electron mobility of the first electron transport layer is greater than 10⁻⁵ cm²/Vs and less than 10⁻⁴ cm²/Vs, the electron mobility of the first buffer layer is greater than 10⁻⁵ cm²/Vs, and the electron mobility of the second buffer layer is greater than 10⁻⁵ cm²/Vs.

6. The display panel of claim 1, wherein an electron work function of the first buffer layer is between an electron work function of the first n-type charge-generating layer and an electron work function of the first p-type charge-generating layer, and an electron work function of the second buffer layer is between the electron work function of the first n-type charge-generating layer and the electron work function of the first p-type charge-generating layer.

7. The display panel of claim 6, wherein the electron work function of the first buffer layer is greater than 5.5 eV and less than 7.5 eV; and
wherein the electron work function of the second buffer layer is greater than 5.5 eV and less than 7.5 eV.

8. The display panel of claim 1, wherein the first n-type charge-generating layer comprises a first electron transport material and a first charge doped material, the first buffer layer is composed of the first electron transport material, and the second buffer layer is composed of the first electron transport material.

9. The display panel of claim 8, wherein a difference between a thickness of the first buffer layer and a thickness of the second buffer layer is greater than or equal to 0 angstrom and less than or equal to 50 angstroms.

10. The display panel of claim 8, wherein a mass ratio of the first electron transport material to the first charge doped material in the first n-type charge-generating layer ranges from 99:1 to 80:20.

11. The display panel of claim 1, wherein the display panel comprises a third buffer layer and a fourth buffer layer, wherein the third buffer layer is disposed between the first p-type charge-generating layer and the second light-emitting layer, and the fourth buffer layer is disposed between the first p-type charge-generating layer and the second buffer layer; and
wherein a hole mobility of the third buffer layer is less than a hole mobility of the first p-type charge-generating layer, and a hole mobility of the fourth buffer layer is less than the hole mobility of the first p-type charge-generating layer.

12. The display panel of claim 11, wherein a difference between a lowest unoccupied molecular orbital energy level of the third buffer layer and a highest occupied molecular orbital energy level of the first p-type charge-generating layer is greater than 2 eV and less than 4 eV; and
wherein a difference between a lowest unoccupied molecular orbital energy level of the fourth buffer layer and the highest occupied molecular orbital energy level of the first p-type charge-generating layer is greater than 2 eV and less than 4 eV.

13. The display panel of claim 11, wherein the display panel comprises a second hole transport layer disposed between the second light-emitting layer and the third buffer layer, wherein a side of the third buffer layer close to the first p-type charge-generating layer is in contact with the first p-type charge-generating layer, and a side of the third buffer layer away from the first p-type charge-generating layer is in contact with the second hole transport layer; and
wherein a side of the fourth buffer layer close to the second buffer layer is in contact with the second buffer layer, and a side of the fourth buffer layer away from the second buffer layer is in contact with the first p-type charge-generating layer.

14. The display panel of claim 13, wherein a difference between a lowest unoccupied molecular orbital energy level of the third buffer layer and a highest occupied molecular orbital energy level of the second hole transport layer is greater than 2 eV and less than 4 eV.

15. The display panel of claim 13, wherein the hole mobility of the first p-type charge-generating layer is greater than or equal to 10⁻² cm²/Vs, the hole mobility of the third buffer layer is less than 10⁻² cm²/Vs, and the hole mobility of the fourth buffer layer is less than 10⁻² cm²/Vs.

16. The display panel of claim 15, wherein a hole mobility of the second hole transport layer is greater than 10⁻⁴ cm²/Vs, the hole mobility of the third buffer layer is greater than 10⁻⁴ cm²/Vs, and the hole mobility of the fourth buffer layer is greater than 10⁻⁴ cm²/Vs.

17. The display panel of claim 11, wherein an electron work function of the third buffer layer is between an electron work function of the first n-type charge-generating layer and an electron work function of the first p-type charge-generating layer, and an electron work function of the fourth buffer layer is between the electron work function of the first n-type charge-generating layer and the electron work function of the first p-type charge-generating layer.

18. The display panel of claim 17, wherein the electron work function of the third buffer layer is greater than 5.5 eV and less than 7.5 eV; and
wherein the electron work function of the fourth buffer layer is greater than 5.5 eV and less than 7.5 eV.

19. The display panel of claim 11, wherein the first p-type charge-generating layer comprises a first hole transport material and a second charge doped material, the third buffer layer is composed of the first hole transport material, and the fourth buffer layer is composed of the first hole transport material.

20. The display panel of claim 19, wherein a difference between a thickness of the third buffer layer and a thickness of the fourth buffer layer is greater than or equal to 0 angstrom and less than or equal to 50 angstroms.
